(19) United States
(12) Patent Application Publication
(10) Pub. No.: US 2024/0250222 A1
(43) Pub. Date: Jul. 25, 2024

(54) ENCAPSULATED QUANTUM CONFINEMENT STRUCTURES AND METHOD OF FABRICATING SAME

(71) Applicant: Technion Research & Development Foundation Limited, Haifa (IL)

(72) Inventors: Yehonadav BEKENSTEIN, Haifa (IL); Rotem STRASSBERG, Haifa (IL)

(73) Assignee: Technion Research & Development Foundation Limited, Haifa (IL)

(21) Appl. No.: 18/421,180

(22) Filed: Jan. 24, 2024

Related U.S. Application Data
(60) Provisional application No. 63/440,707, filed on Jan. 24, 2023.

(51) Int. Cl. H01L 33/56; B29C 64/118; B29K 27/12; B29K 33/00; B29K 105/00; B29K 509/02; B29L 31/00; B33Y 10/00; B33Y 70/00; B33Y 80/00; D01D 1/02; D01D 5/00; D01F 1/10; D01F 6/12; D01F 6/16; H01L 33/58

(52) U.S. Cl. CPC H01L 33/56; B29C 64/118; B33Y 10/00; B33Y 70/00; B33Y 80/00; D01D 1/02; D01D 5/003; D01F 1/10; D01F 6/12; D01F 6/16; H01L 33/58; B29K 2027/12; B29K 2033/12; B29K 2105/0005; B29K 2509/02; B29L 2031/747; D10B 2321/042; D10B 2321/08; D10B 2505/00; H01L 2933/005; H01L 2933/0058

(57) ABSTRACT

A method of fabricating a light emitting device, comprises mixing a first solution containing a polymeric component with a second solution containing quantum-confinement structures, to provide a solution mixture, and dispensing the solution mixture to form a fiber. The fiber is allow to be self-drawn such that at least one section of the fiber has a reduced diameter relative to another section.

### RELATED APPLICATION

This application claims the benefit of priority under 35 USC § 119(e) of U.S. Provisional Patent Application No. 63/440,707 filed on Jan. 24, 2023, the contents of which are incorporated herein by reference in their entirety.

### FIELD AND BACKGROUND OF THE INVENTION

The present invention, in some embodiments thereof, relates to optics and, more particularly, but not exclusively, to an encapsulated quantum confinement structures and method of fabricating same.

Lead halide perovskites (LHPs) are highly investigated in recent years due to their outstanding optical properties and rapid development in solar cell aplication^{1,2} and optoelectronic devices^{3,4}. LHP has a stoichiometry of APbX₃, where the A atoms are mono-valent cations, such as cesium for all-inorganic perovskites, or Methylammonium (MA) or Formamidinium (FA) for organic-inorganic LHPs. The X atoms are mono-valent halide anions, including chlorine, bromine, iodine, or a combination of them. The halides form octahedrons around bi-valent lead cations, and the A atoms are placed in between the octahedrons, holding the structure together and neutralizing the charge.

The success of bulk perovskites inspired the intensive research of colloidally grown LHP nanocrystals (NCs) that showed superior optical properties, including high photoluminescent quantum yield (PLQY), narrow spectral width, short radiative lifetimes, and high defect tolerance^{5,6,7,8}. Moreover, one of the most interesting properties of LHPs nanocrystals is their band gap tunability^{5,9,10}.

### SUMMARY OF THE INVENTION

According to an aspect of some embodiments of the present invention there is provided a method of fabricating a light emitting device. The method comprises: mixing a first solution containing polymeric component with a second solution containing quantum-confinement structures, to provide a solution mixture; dispensing the solution mixture to form a fiber, wherein the dispensing is while allowing the fiber to be self-drawn such that at least one section of the fiber has a reduced diameter relative to another section.

According to some embodiments of the invention the second solution comprises perovskite quantum-confinement structures.

According to some embodiments of the invention the method comprises applying surface treatment to the quantum-confinement structures in the second solution with an anion before the mixing with the first solution containing said polymeric component.

According to some embodiments of the invention the anion comprises thiocyanate.

According to some embodiments of the invention surface treatment comprises adding urea ammonium thiocyanate (UAT) to the second solution.

According to some embodiments of the invention the polymeric component comprises (meth) acrylic polymer component. According to some embodiments of the invention the polymeric component comprises polymethyl methacrylate (PMMA).

According to some embodiments of the invention the polymeric component comprises a perfluorinated polymer component. According to some embodiments of the invention the perfluorinated polymer component comprises polyperfluorobutenyl vinyl ether.

According to some embodiments of the invention the perfluorinated polymer component comprises a fluorinated polymer component.

According to some embodiments of the invention the dispensing is by three-dimensional printing.

According to some embodiments of the invention the dispensing is by extrusion.

According to some embodiments of the invention the dispensing is by electrospinning.

According to some embodiments of the invention the dispensing is over a gap between two substrates, wherein the at least one section of the reduced diameter is over the gap, and the other section is supported by at least one of the substrates.

According to some embodiments of the invention at least one of a concentration of the first solution, a concentration of the second solution, and a mixing ratio of the solution mixture is selected to ensure that the section of the reduced diameter contains a single quantum-confinement structure throughout its length.

According to an aspect of some embodiments of the present invention there is provided a light emitting device, producible by the method as delineated above and optionally and preferably as further detailed below.

According to an aspect of some embodiments of the present invention there is provided a light emitting device, comprising a single quantum-confinement structure encapsulated in a polymeric optical fiber, wherein a length of the fiber is from about 100 μm to about 10 mm, and a diameter of the fiber is from about 0.1 μm to about 20 μm.

According to an aspect of some embodiments of the present invention there is provided a quantum computer which comprises the light emitting device as delineated above and optionally and preferably as further detailed below.

According to an aspect of some embodiments of the present invention there is provided a quantum communication system which comprises the light emitting device as delineated above and optionally and preferably as further detailed below.

According to an aspect of some embodiments of the present invention there is provided a quantum cryptology system which comprises the light emitting device as delineated above and optionally and preferably as further detailed below.

According to some embodiments of the invention the quantum-confinement structures comprise quantum dots.

According to some embodiments of the invention the quantum-confinement structures comprise quantum wires.

According to some embodiments of the invention the quantum-confinement structures comprise quantum wells.

According to some embodiments of the invention the quantum-confinement structures comprise perovskite quantum-confinement structures.

According to some embodiments of the invention the perovskite quantum-confinement structures comprise perovskite quantum-dots.

According to some embodiments of the invention at least a portion of the perovskite quantum-confinement structures comprises CsPbX₃, wherein X is selected from the group consisting of Cl, Br, and I.

According to some embodiments of the invention at least a portion of the perovskite quantum-confinement structures comprises MAPbX₃, wherein X is selected from the group consisting of Cl, Br, and I.

According to some embodiments of the invention at least a portion of the perovskite quantum-confinement structures are CsPbBr₃.

According to some embodiments of the invention each of the perovskite quantum-confinement structures is CsPbBr₃.

According to some embodiments of the invention at least a portion of the perovskite quantum-confinement structures comprises double perovskite quantum-confinement structures.

According to some embodiments of the invention the quantum-confinement structures comprise binary compound quantum-confinement structures.

According to some embodiments of the invention at least a portion of the binary compound quantum-confinement structures are selected from the group consisting of lead sulfide, lead selenide, cadmium selenide, cadmium sulfide, cadmium telluride, indium arsenide, and indium phosphide.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

The patent or application file contains at least one drawing executed in color. Copies of this patent or patent application publication with color drawing(s) will be provided by the Office upon request and payment of the necessary fee.

Some embodiments of the invention are herein described, by way of example only, with reference to the accompanying drawings and images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A and 1B show relative quantum yield as a function of soaking time in water of as-synthesized QDs (FIG. 1A) compared to encapsulated QDs in SEBS (FIG. 1B). Pictures showing samples under UV excitation before and after mentioned time of water soaking.

FIG. 2A is a schematic representation of an HBT setup FIG. 2B shows classification of light sources according to the g₂(τ) value at τ=O.

FIG. 2C shows a g₂(τ) function measured for single CsPbI₃ QD under CW laser excitation.

FIG. 2D shows a g₂(τ) function measured for single CsPbI₃ QD under pulsed laser excitation.

FIGS. 3A-C are schematic illustrations showing examples for different waveguide geometries, where FIG. 3A illustrates a planar waveguide, FIG. 3B illustrates a channel waveguide, and FIG. 3C illustrates an optical fiber.

FIG. 4 shows electric field intensity profiles for guided modes of an optical fiber.

FIG. 5A is a schematic illustration of a Hyrel Engine HR 3D printer, loaded with QDs/PMMA solution, according to some embodiments of the present invention.

FIG. 5B is a schematic illustration of printed polymer filaments, according to some embodiments of the present invention.

FIG. 5C is a schematic illustration of suspended polymer fibers, according to some embodiments of the present invention.

FIG. 6A is a TEM micrograph revealing the cube shape of the CsPbBr₃ QDs with a narrow size dispersion, as obtained in experiments performed according to some embodiments of the present invention.

FIG. 6B is a HRTEM micrograph showing the interplanar distances of the perovskite structure, as obtained in experiments performed according to some embodiments of the present invention.

FIG. 6C shows measured XRD pattern compared to cubic CsPbBr₃ reference, as obtained in experiments performed according to some embodiments of the present invention.

FIG. 7A is an image of a CsPbBr₃ solution under ambient light, as obtained in experiments performed according to some embodiments of the present invention.

FIG. 7B is an image of a CsPbBr₃ solution under UV light, as obtained in experiments performed according to some embodiments of the present invention.

FIG. 7C shows normalized absorption and emission spectra at room temperature, as obtained in experiments performed according to some embodiments of the present invention. Sharp emission peak is noticed around 510 nm wavelength.

FIG. 8A is an image of a printed filament, as obtained in experiments performed according to some embodiments of the present invention.

FIG. 8B is a zoom-in image of a printed filament consisted of 20% wt PMMA in toluene, printed using a 27G needle, as obtained in experiments performed according to some embodiments of the present invention. Average width of the five lines is 510±40 μm. The scale bar is 200 m long.

FIGS. 9A-C show scanning confocal fluorescence microscopy scan of a printed filament, as obtained in experiments performed according to some embodiments of the present invention. FIG. 9A shows an optical image of the printed filament on silicon substrate, where the dark rectangle indicates the scanned area and the bright spots are where QDs were detected. The QDs showing random distribution inside the PMMA filaments. Each color represents different photoluminescent spectra as presented in FIG. 9B, which shows PL spectra of the encapsulated QDs. Some spectra showing intensity modulation that indicates photonic effect. FIG. 9C shows a chosen emission spectrum showing intensity modulation (blue). The dashed lines represent the calculated wavelengths for a standing wave in 8.6 μm layer.

FIG. 10A is an optical image of the printed filament on silicon substrate. The red rectangle indicates a scanned area and the edge of a PMMA layer, as obtained in experiments performed according to some embodiments of the present invention.

FIG. 10B shows distribution of the PL intensity in the scanned area of FIG. 10A, as obtained in experiments performed according to some embodiments of the present invention. The QDs are showing random distribution inside the PMMA filaments.

FIG. 11A is a schematic illustration of a printed filament and refractive indexes for 510 nm wavelength, as obtained in experiments performed according to some embodiments of the present invention.

FIG. 11B shows three first TE modes that are supported by a simulated waveguide, as obtained in experiments performed according to some embodiments of the present invention. The existence of supported modes validates that the printed filament is acting as a waveguide for the emission wavelength of the QDs.

FIG. 12A is a schematic illustration of a single QD measurements setup, used in experiments performed according to some embodiments of the present invention. Confocal mode: only one QD is measured and the PL emission is directed into an HBT setup.

FIG. 12B shows measured second order correlation function, as obtained in experiments performed according to some embodiments of the present invention. The normalized g₂(0) value was calculated for 22 individual QDs and found to be 22±14%, indicating single photon emission.

FIG. 12C shows lifetime measurement demonstrating two exponential decay rates, as obtained in experiments performed according to some embodiments of the present invention. The average decay rates for the measured QDs was 1.6±0.4 ns for the fast decay, indicative of trions or biexcitons, and 10±2 ns for the slow decay rate, indicative of excitons.

FIG. 13 shows lifetime measurement showing two exponential decay rates, as obtained in experiments performed according to some embodiments of the present invention. The average decay rates for the measured QDs was 1.6±0.4 ns for the fast decay and 10±2 ns for the slow decay rate.

FIGS. 14A and 14B show emission intensity as a function of number of excitation cycles for non-encapsulated QDs (FIG. 14A) and printed QDs in PMMA filament (FIG. 14B), as obtained in experiments performed according to some embodiments of the present invention. the number of excitation cycles before the intensity drops by an exponential factor is mentioned.

FIGS. 15A and 15B show optical images of a suspended PMMA/QDs fiber, as obtained in experiments performed according to some embodiments of the present invention. FIG. 15A shows PMMA/QDs solution that was printed on top of two glass slides with a varying distance as illustrated in the inlet. Suspended fibers were formed in the gap between the two slides. FIG. 15B is zoomed-in optical image of the suspended fiber at the contact point with one of the glass slides.

FIGS. 16A and 16B show PMMA/QDs suspended fibers characterization, as obtained in experiments performed according to some embodiments of the present invention. FIG. 16A shows HRSEM micrograph showing the cylindrical shape of two PMMA/QDs fibers. FIGS. 16A and 16B show scanning confocal fluorescence microscopy scan of a suspended fiber. FIG. 16B is an optical image of the printed filament on a silicon substrate, showing where QDs were detected (red and green spots). The QDs showing random distribution inside the PMMA fiber. Each color represents different photoluminescent spectra as presented in FIG. 16C, which shows PL spectra of the encapsulated QDs.

FIGS. 17A-D show fluorescence microscopy of encapsulated QDs in PMMA fibers under white light (FIGS. 17A and 17C), and under UV excitation (FIGS. 17B and 17D), as obtained in experiments performed according to some embodiments of the present invention. Bright luminescence is observed at the edge of the fibers.

FIGS. 18A and 18B show a 2D Ray optics simulation of few point light sources in a rectangular with 1.5 refractive indexes (FIG. 18A) and an experimental optical image of QDs in PMMA fiber under UV excitation (FIG. 18B), as obtained in experiments performed according to some embodiments of the present invention. The simulated image showing similar pattern of light propagation to the optical image.

FIG. 19 shows three first TE modes that are supported by the simulated optical fiber, as obtained in experiments performed according to some embodiments of the present invention. The existence of supported modes validates that the PMMA fibers are acting as an optical fiber for the emission wavelength of the QDs.

FIG. 20 shows PL emission, as obtained in experiments performed according to some embodiments of the present invention demonstrating increased emission intensity with volumetric addition of UAT. Photograph of treated NCs solution excited at UV (365 nm), (inset) Notable increase to brightness and emission by addition of UAT.

FIG. 21A sows HAADF micrographs of the perovskite nanocrystal used to acquire EELS mapping (see, FIGS. 21B and 21C).

FIGS. 21B and 21C shows the EELS mapping acquired at 60 keV.

FIG. 21D is a schematic illustration of a surface treatment process applied according to some embodiments of the present invention.

FIG. 21E shows solubility saturation curve of SCN-peak area as a function of ligand volume fraction.

FIGS. 22A and 22B show PL emission demonstrating increased emission intensity with volumetric addition, as obtained in experiments performed according to some embodiments of the present invention.

FIG. 22C shows PL lifetime of treated and untreated nanocubes with exponential fitting, as obtained in experiments performed according to some embodiments of the present invention.

FIG. 22D is a schematic illustration of UAT treatment consisting of two passivation steps, as performed in experiments performed according to some embodiments of the present invention.

FIGS. 23A-F show HAADF (FIGS. 23A-B) S/TEM (FIGS. 23C-D) and TEM (FIGS. 23E-F) samples of treated CsPbBr3 nanocrystals, as obtained in experiments performed according to some embodiments of the present invention.

FIG. 24A is a schematic illustration of ion exchange experiment performed according to some embodiments of the present invention.

FIGS. 24B and 24C show pristine and UAT treated nanocubes insitu PL anion exchange experiment with the halides I— and Cl—, obtained in experiments performed according to some embodiments of the present invention. The Kinetics suggest that surface diffusion processes are limited when treated with UAT.

FIG. 24D shows central emission wavelength as a function of the time, as obtained in experiments performed according to some embodiments of the present invention.

FIG. 25 is a flowchart diagram of a method suitable for fabricating a light emitting device according to some embodiments of the present invention.

FIGS. 26A and 26B are schematic illustrations of a process for dispensing a fiber (FIG. 26A) and a section of a fiber (FIG. 26B), according to some embodiments of the present invention.

### DESCRIPTION OF SPECIFIC EMBODIMENTS OF THE INVENTION

The patent or application file contains at least one drawing executed in color. Copies of this patent or patent application publication with color drawing(s) will be provided by the Office upon request and payment of the necessary fee.

The present invention, in some embodiments thereof, relates to optics and, more particularly, but not exclusively, to an encapsulated quantum confinement structures and method of fabricating same.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

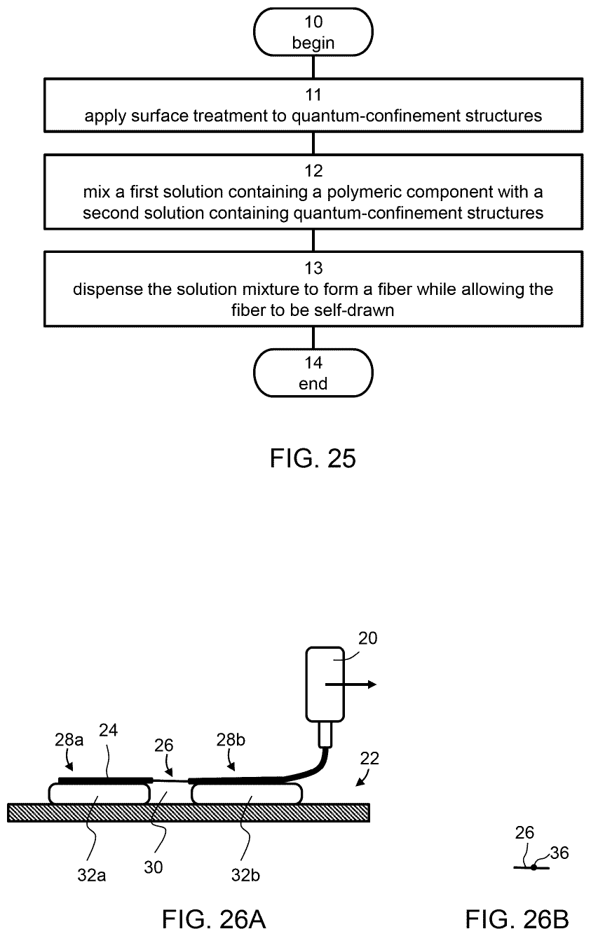

Referring now to the drawings, FIG. 25 is a flowchart diagram of a method suitable for fabricating a light emitting device according to various exemplary embodiments of the present invention. It is to be understood that, unless otherwise defined, the operations described hereinbelow can be executed either contemporaneously or sequentially in many combinations or orders of execution. Specifically, the ordering of the flowchart diagrams is not to be considered as limiting. For example, two or more operations, appearing in the following description or in the flowchart diagrams in a particular order, can be executed in a different order (e.g., a reverse order) or substantially contemporaneously. Additionally, several operations described below are optional and may not be executed.

The method begins at 10. At 12 a first solution containing a polymeric component is mixed with a second solution containing quantum-confinement structures, to provide a solution mixture. The quantum-confinement structures can be of any type which exhibits quantum-confinement.

The term “quantum confinement,” as used herein refers to a phenomenon in which there are quantized energy levels in at least one dimension.

A structure exhibits quantum confinement when the positions of charge carriers (electrons or holes) in the structure are confined along at least one dimension. A structure in which the charge carriers are confined along one dimension but are free to move in the other two dimensions is referred to herein as a “two-dimensional quantum confinement structure,” since the structure allows free motion in two dimensions. A structure in which the charge carriers are confined along two dimensions but and are free to move only in one dimension is referred to herein as a “one-dimensional quantum confinement structure,” since the structure allows free motion in one dimension. A structure in which the charge carriers are confined along all three dimensions, namely a structure in which the charge carriers are localized, is referred to herein as a “zero-dimensional quantum confinement structure,” since the structure does not allow free motion.

A two-dimensional quantum confinement structure is interchangeably referred to herein as a quantum well structure, a one-dimensional quantum confinement structure is interchangeably referred to herein as a quantum wire structure, and a zero-dimensional quantum confinement structure is interchangeably referred to herein as a quantum dot structure.

In various exemplary embodiments of the invention the length of the smallest dimension along which a quantum confinement occurs is in the nanometer range, preferably below 50 nm or below 40 nm or below 30 nm or below 20 nm or below 10 nm or below 5 nm.

Quantum confinement can be verified by examining the optical properties of the structure. For quantum confinement structures, the optical properties are significantly different from other structures since the optical absorption coefficient is defined by density of states (DOS) of the charge carriers. For a structure which does not exhibits any quantum confinement the DOS is proportional to the square root of the energy. For a quantum confinement structure, the DOS quantized.

In some embodiments of the present invention the second solution comprises perovskite quantum-confinement structures.

As used herein “perovskite” designate metal oxides having an ideal and non-ideal perovskite crystalline structure. The ideal perovskite crystalline structure is defined by the empirical formula ABO₃ in which A and B are cations of different metals and in which the A cation is coordinated to 12 oxygen atoms while the B cation occupies octahedral sites and is coordinated to 6 oxygen atoms. The ideal perovskite structure is cubic, while the non-ideal perovskite structure is not necessarily a cubic structure. The algebraic sum of the ionic charges of the two metals (cations) of the perovskite typically equals 6.

Representative examples of perovskite quantum-confinement structures suitable for the present embodiments include, without limitation, CsPbX₃, and MAPbX₃, wherein X is selected from the group consisting of Cl, Br, and I. In some embodiments of the present invention one or more of the perovskite quantum-confinement structures, for example, each of the perovskite quantum-confinement structures, is CsPbBr₃.

Further contemplated, are embodiments in which one or more of the perovskite quantum-confinement structures is a double perovskite quantum-confinement structure. Representative examples of double perovskite quantum-confinement structures suitable for the present embodiments include, without limitation, doped Cs₂NaInCl₆, and Cs₂Ag_{0.4}Na_{0.6}In₁₋ₓBiₓCl₆.

In some embodiments of the present invention one or more of the quantum-confinement structure is a perovskite quantum-dot.

In some embodiments of the present invention one or more of the quantum-confinement structure is a binary compound quantum-confinement structure. Representative examples of binary compounds quantum-confinement structures suitable for the present embodiments include, without limitation, lead sulfide, lead selenide, cadmium selenide, cadmium sulfide, cadmium telluride, indium arsenide, and indium phosphide.

The present embodiments also contemplate configurations in which one or more of the quantum-confinement structures has a core-shell structure. Representative examples of quantum-confinement structure having a core-shell structure that are suitable for the present embodiments include, without limitation, CdS/ZnS, CdSe/ZnS, CdSe/CdS, and InAs/CdSe.

Additionally contemplated, are embodiments in which one or more of quantum-confinement structure is metallic. Representative examples of metallic quantum-confinement structures suitable for the present embodiments include, without limitation, single element metallic quantum dots, such as, but not limited to, Si quantum dots, Ge quantum dots, and C quantum dots, and multi-element metallic quantum dots, such as, but not limited to, InGaAs quantum dots.

The solution containing the quantum-confinement structures preferably comprises an organic solvent, such as, but not limited to, a hydrocarbon solvent, e.g., toluene, hexane, octane, decane and the like, in which the quantum-confinement structures are immersed.

In some embodiments of the present invention 12 is preceded by 11 at which a surface treatment is applied to the quantum-confinement structures in the second solution. Preferably, the surfaces of the quantum-confinement structures are treated with an anion. In some embodiments of the present invention the anion comprises thiocyanate. These embodiments are particularly useful when perovskites are employed as the quantum-confinement structures. For example, operation 11 can be executed by adding urea ammonium thiocyanate (AUT) to the second solution. Further details regarding surface treatments suitable for the present embodiments and the advantages offered thereby are provided in the Examples section that follows.

The polymeric component of the first solution can, in some embodiments of the invention, comprise a (meth) acrylic polymer component, such as, but not limited to, polymethyl methacrylate (PMMA). Also contemplated are embodiments in which the polymeric component comprises a fluorinated polymer component, such as, but not limited to, a perfluorinated polymer component, e.g., polyperfluorobutenyl vinyl ether.

Once a solution mixture is obtained by mixing the first and second solutions, the method proceeds to 13 at which the solution mixture is dispensed to form a fiber. Preferably, the fiber is a polymeric fiber. In some embodiments of the present invention the fiber is an optical fiber. The fiber can have any cross-sectional shape, including, without limitation, a round shape, a flat shape, and filament shape.

The dispensing is optionally and preferably executed in a manner that the fiber is allowed to be drawn, e.g., self-drawn, such that at least one section of the fiber has a reduced diameter relative to another section. This process is illustrated in FIGS. 26A-B. Shown is a dispensing device 20 and a working platform 22 at a relative motion therebetween (in the schematic illustration of FIG. 26A, which is not to be considered as limiting, dispensing device 20 moves relative to platform 22, as indicated by the arrow). During the relative motion, dispensing device 20 dispenses a fiber 24 over planform 22. Due to friction forces between fiber 24 and platform 22, the fiber is drawn during the motion, forming a section 26 with a reduced diameter relative to other sections 28a, 28b. Preferably, the dispensing is over a gap 30 between two substrates 32a, 32b, wherein section 26 is formed over gap 30 and sections 28a and 28b are supported by one or more of substrates 32a 32b. The substrates 32a and 32b can be placed over platform 22, as illustrated in FIG. 26A, or be an integral part of platform 22. Once section 26 is formed, it can be isolated from fiber 24 as illustrated in FIG. 26B, for example, by a suitable cutting device (not shown).

The dispensing can be using any type of dispensing device suitable for forming a continuous fiber or filament. Representative examples of dispensing techniques suitable for the present embodiments, include, without limitation, three-dimensional printing, in which case device 20 can be a printhead of a three-dimensional printing system, extrusion, in which case device 20 can be a die of an extruder system, and electrospinning, in which case device 20 can be a spinneret of an electrospinning system.

It is expected that during the life of a patent maturing from this application many relevant fiber forming techniques will be developed and the scope of the term “dispensing” is intended to include all such new technologies a priori.

During the process in which the fiber is drawn, the density of quantum-confinement structures per unit length of the fiber is reduced. In some embodiments of the present invention the concentration of first solution, the concentration of the second solution, and/or the mixing ratio of the solution mixture is/are selected to ensure that section 26 contains a single quantum-confinement structure 36 throughout its length. These embodiments are useful in any electronic, optical, or optoelectronic system that require single quantum-confinement structures, e.g., single quantum-dots. Representative example of such systems include, without limitation, single-photon light sources, quantum sensors, single-qubit elements in quantum computers, and single electron transistors.

In some embodiments of the present invention section 26 has a length of from about 100 μm to about 10 mm, and a diameter of from about 0.1 μm to about 20 μm. Preferably, section 26 comprises a single quantum-confinement structure.

Section 26 can therefore be incorporated in a light emitting device, a quantum computer, quantum cryptology system, or quantum communication system, as desired.

The method ends at 14.

As used herein the term “about” refers to ±10% The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

This Example describes a 3D printing method of single CsPbBr₃ QDs encapsulated in polymeric matrices that enables accurate positioning and enhances the stability of the QDs. The self-drawn fiber waveguides containing single-photon emitters that can be positioned with micrometric resolution. The quantum nature of the emitters was demonstrated through second-order correlation measurements, and the protective properties of the polymer are clear with a 15-fold enhancement of the number of single-photon emission cycles.

A method of 3D printing to form suspended fibers that are significantly thinner in their diameter and act as optical fibers for the single photons is demonstrated.

A large scaling method using electro spinning and an industrial extruded is also described.

The structure of the present embodiments can be used for coupling single CsPbBr₃ QDs into photonic structures or photonic circuits toward future quantum communication on-a-chip devices.

Lead halide perovskites (LHPs) are highly investigated in recent years due to their outstanding optical properties and rapid development in solar cell aplication^{1,2} and optoelectronic devices^{3,4}. LHP has a stoichiometry of APbX₃, where the A atoms are mono-valent cations, such as cesium for all-inorganic perovskites, or Methylammonium (MA) or Formamidinium (FA) for organic-inorganic LHPs. The X atoms are mono-valent halide anions, including chlorine, bromine, iodine, or a combination of them. The halides form octahedrons around bi-valent lead cations, and the A atoms are placed in between the octahedrons, holding the structure together and neutralizing the charge.

The success of bulk perovskites inspired the intensive research of colloidally grown LHP nanocrystals (NCs) that showed superior optical properties, including high photoluminescent quantum yield (PLQY), narrow spectral width, short radiative lifetimes, and high defect tolerance^{5,6,7,8}. Moreover, one of the most interesting properties of LHPs nanocrystals is their band gap tunability^{5,9,10}. Protesescu et al. were the first to demonstrate the tunability of the emission wavelength of LHP quantum dots (QDs) over the entire visible spectral region by controlling their composition and particle sizes.

For composition tunability, different ratios of Cl/Br and I/Br halides were used. The reason for the band gap dependence on the halide ratio can be explained by density functional theory (DFT) calculations, which have shown that the electronic structure of CsPbX₃ is strongly dependent on the halide atoms, since the upper valence band is formed by the hybridization of the halide p orbitals with the lead s orbitals⁸.

The control over particle sizes was done by changing the reaction temperature and can be explained by the quantum nature of nanoparticles. For nanoscale particles, the charge carriers' movement is confined to an area on the order of the excitonic Bohr radius or smaller, which causes a quantization of the particles' energy levels^{11,12}. The discrete energy spectrum leads to an increase of the band gap, which inversely depends on the particle size, and thus, to a blue shift of the absorption and emission spectra¹³. This effect, known as the quantum size effect, was documented in different metal and semiconductor nanoparticles for various shapes such as nanocubes^{5,14}, nanoplates⁶, and nanowires¹⁵.

Thanks to all of the listed advantages, LHP nanocrystals are great candidates for many light-based applications and technologies, such as light emitted diodes (LEDs)¹⁶, solar cells¹⁷, lasers¹⁸, and photodetectors¹⁹. Moreover, due to the ability of LHP QDs to emit single photons on demand, they are of great potential to serve as a base for photon-based quantum technologies, which will be elaborated below.

LHP QDs can be synthesized by colloidal methods in which QDs are produced from their precursors' solutions that are mixed under controlled temperature and pressure. In this Example, a hot injection method was chosen to synthesize CsPbBr₃ QDs. In this method, a final precursor is quickly injected into a hot solution containing the rest of the precursors and the ligands under an inert atmosphere²⁰. The rapid injection initiates the nucleation of the nanoparticles. Their growth is controlled by varying the temperature and time, then stopped by fast cooling of the solution²¹. Another crucial parameter that affects the growth, size, and QDs' stability is the presence of organic ligands. By binding to the nanoparticle facets, the ligands can induce anisotropic growth to affect nanocrystals' shape, passivate surface defects and prevent aggregation of particles^{22,23,24}.

### Stability and Photodegradation

The Inventors found that LHP QDs suffer from a significant disadvantage of poor stability, which hinders their integration into the industry and complicates fundamental studies. The instability limits the performance of potential devices on the one hand, and may result in the release of toxic lead ions as a result of decomposition on the other hand. To date, most studies of perovskite QDs stability were performed on organic-inorganic LHPs, so a profound understanding of the degradation process in CsPbBr3 QDs has not yet been achieved. However, many factors have been found to contribute to the degradation processes of perovskites, including moisture^{26,27}, thermal effects^{28,29}, oxygen 3031, and light exposure (i.e., photobleaching)^{28,32}.

Additionally, the colloidal solution of perovskite QDs frequently experiences a loss of colloidal stability and aggregation of the nanocrystals. This process occurs in long storage times and under purification³³, limiting shelf life and creating problems in operation and device fabrication. Moreover, it was found to accelerate under light excitation above the optical band-edge³⁴ and was noticed both from aggregation and from the reduction of absorbance that was attributed to a formation of surface or interface trap sites.

Other research investigated the degradation of single CsPbI₃ QDs under various environmental conditions, including air, dry nitrogen, wet nitrogen, dry oxygen, and wet oxygen, and under laser exitation²⁷. The increase in degradation was attributed independently to humidity and light, while the presence of oxygen showed no significant influence compared to the nitrogen environment. The degradation of QDs is manifested in the loss of optical properties, which includes both the reduction of the emission intensity as well as a blue shift of the emitted light²⁷. These effects can be attributed to a gradual decomposition of the QDs, layer by layer, which reduces the size of the nanocrystals. The decreased size causes a blue shift in the emitted light due to the quantum size effect and a decrease in the absorption cross-section, leading to reduced absorption and emission of light.

### Polymer Encapsulation

Numerous strategies have been suggested over the recent years to increase stability and enhance the optical performances of LHP QDs²⁵. Some of these strategies are A-site doping which showed to improve the stability while preserving the optical characteristics^{35,36}, B-site doping which can contribute to the stability while tuning the optical characteristics^{37,38}, and surface treatments, during or post-synthesis, which showed the ability to increase the stability by passivating surface defects as well as by eliminating the access of oxygen and water molecules to the QD surface^{39,40}, and more.

However, the most widely used method today of increasing the stability of QDs is through polymer encapsulation due to the simplicity of this method and its compatibility with many types of QDs⁴¹. Encapsulating the QDs in a polymer matrix can protect them from contact with the environment and improve water resistivity and, in some cases, can passivate surface traps and result in increased photoluminescence (PL)⁴².

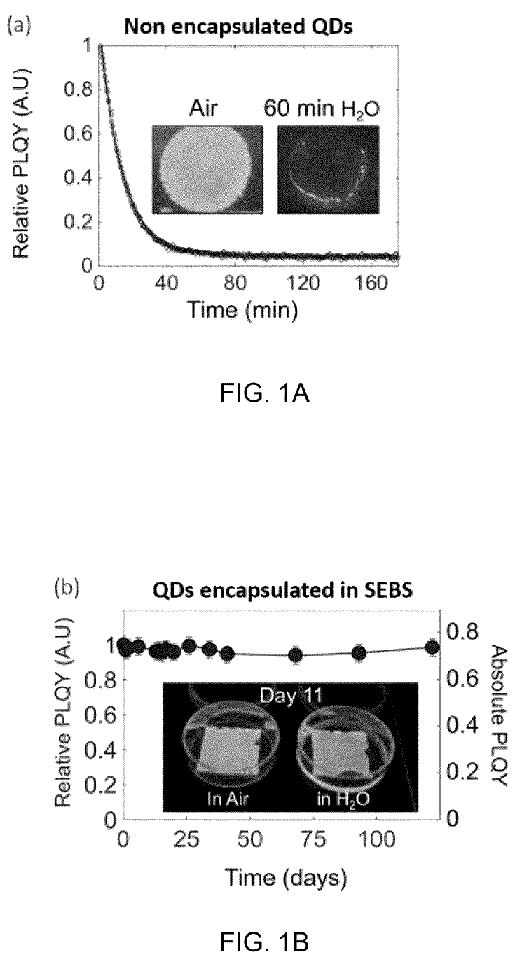

An example of the enhanced stability by polymer encapsulation was performed by Raja et al., where CsPbBr₃ QDs were encapsulated in poly(styrene-ethylene-butylene-styrene) (SEBS)². The encapsulated QDs preserved their PLQY under soaking in water for over 100 days, while similar non-encapsulated QDs lost their optical properties within an hour (FIGS. 1A-B). Moreover, the encapsulated QDs showed increased stability under constant laser illumination.

Polymer encapsulation can be achieved using a variety of polymers, while some main parameters should be considered. On one hand, decreased water permeability of the polymer may lead to an increased repulsion of water molecules and, therefore, to a more efficient encapsulation. On the other hand, the hydrophobicity of the chosen polymer can lead to enhanced degradation of the QDs since they demand high polarity solvents. That leads to the separation of ligands from the surface and degradation of the particle due to its ionic composition. Moreover, the hydrophobicity of the polymer can lead to aggregation of the QDs, which is undesirable for single QDs-based applications and studies.

Raino et al. studied four different polymers, including Polymethyl methacrylate (PMMA), TOPAS, SEBS, and polystyrene (PS) for their hydrophobicity and their effect on single QDs stability under laser illumination⁴³. No correlation was found between water permeability and stability of the QDs, since the most effective polymer was found to be PS, although it has a 50 times higher water permeability coefficient than TOPAS. This result led to the conclusion that the most significant parameter for effective encapsulation is the interfacial contact of the polymer with the ligands, where polar groups in the polymer result in only partial coverage of the QDs by ligands.

Such encapsulated QDs are proven to have stable enough emission and serve as good single-photon sources.

### Single Photon Sources

Single photon sources (SPS), also known as quantum emitters, can serve as a base for quantum technologies such as quantum computation and quantum communication that are based on photonic quantum bits (also known as qubits)^{46,47}. The most straightforward realization of photon-based qubits is done by defining the polarization of light as the quantum states of the qubit. For example, the quantum states 0 and 1 are represented by horizontal and vertical photon polarizations |0 [symbol] =↔ and |1 [symbol] = [symbol] and their superposition corresponds to other possible polarizations. Furthermore, quantum gates can be applied on these qubits by using optical elements such as quarter and half-wave plates to perform quantum computation scheames⁴⁷.

Some known single photon sources are single atoms⁴⁸, single molecules⁴⁹, nitrogen vacancy centers in diamonds⁵⁰, carbon nanotubes⁵¹, and single QDs. Single QDs were first demonstrated for their ability to emit single photons by Michler et al. for CdSe QDs⁵², and later it was also demonstrated for other QDs, including perovskite nanocrystals^{53,54}.

Preferably, the SPS of the present embodiments has at least one of the following characteristics, which are particularly useful for quantum technology applications: (i) high purity of single photons: ideal SPS should emit only one photon per excitation pulse; (ii) fast radiative lifetimes to allow fast computation; (iii) photo-stable emission without blinking or photobleaching; (iv) high PLQY, preferably close to 100%, providing a reliable photon source in which every excitation pulse produces a photon; (v) room temperature operation; (vi) long coherence time, where the coherence time is defined as the time duration over which the photon retains its quantum state; and (vii) scalability for industrial fabrication.

LHP QDs have high PLQY and short radiative lifetime⁵⁻⁶, high purity of single photons at room temperatures^{3,54}, long coherence time⁵⁶ and improved PL stability at cryogenic temperature⁵⁷. However, the inventors found that there are some challenges with these materials for SPS applications. These include a low photo-stability of the as-synthesized QDs at room temperature, which is reflected in both blinking behavior and photobleaching, and a lack of scalable manufacturing method for SPS-oriented samples. LHP QDs are highly affected by temperature and suppressed upon cooling to 230K for MAPbI₃ NCs⁶⁸. By vacancy filling using post-synthesis treatment with halide precursors⁶⁹, blinking can be suppressed and PLQY can be increased.

### Photon Antibunching

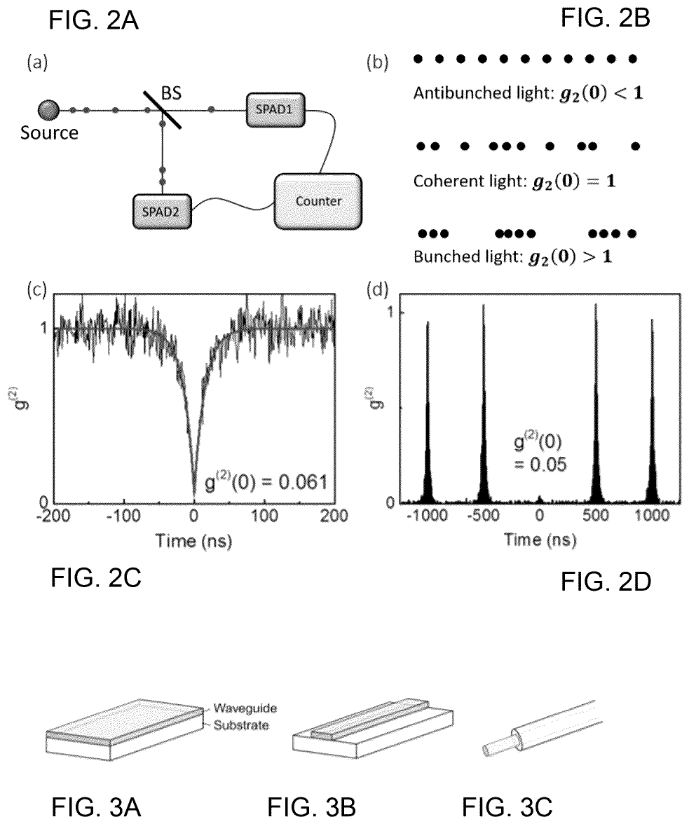

A Hanbury Brown and Twiss (HBT) experiment can be performed according to some embodiments of the present invention to test whether a light source can serve as a SPS. Hanbury Brown and Twiss originally proposed this experiment to measure star diameters by the patterns of interference of the emitted light from the star⁷⁰. The same principles can be applied in modern HBT setups to study the nature of light sources and classify them. In a basic HBT setup, the light is split by a 50:50 beam splitter (BS) and sent into two single-photon detectors. The detectors are connected to correlation electronics that measure the time delay between the detection events (FIG. 2A).

The output from this experiment is a second-order correlation function (g₂(τ) function) which is proportional to the conditional probability of detecting a photon at time t=τ, given that a first photon was detected at time t=0.

$${g}_{2} ( τ ) = \frac{〈 \text{?} ( t ) {n}_{2} ( t + τ ) 〉}{〈 \text{?} ( t ) 〉 〈 {n}_{2} ( t + τ ) 〉} \qquad ( 1 )$$

$$\text{?} \text{indicates text missing or illegible when filed}$$

where nᵢ(t) is the number of counts measured by detector i at time t, and τ is the time delay between the detection events.

Based on the value of the zero time delay peak (g₂(0)), the light can be classified as antibunched, random, or bunched light⁷¹ as specified in FIG. 2B.

For an ideal SPS, only one photon is emitted at a time. Therefore, for zero-time delay, the two detectors are not correlated, and the g₂(0) function is expected to zeroed. This is known as photon antibunching. FIGS. 2C-D presents an example of an experimental g₂(τ) function for a single CsPbI₃ QD under continuous wave (CW) and pulsed excitation, respectively.

From an experimental point of view, a measurement result of g₂(0)<0.5 is considered unequivocal proof that the light source can serve as a SPS. For QD measurement, it serves as a proof that the examined QD is a single QD, since a cluster of n QDs would yield⁵⁷:

$${g}_{2} ( 0 ) \geq 1 - \frac{1}{n} \qquad ( 2 )$$

As a result of the simplicity and reliability of these experiments, HBT measurements can be used for single QD characterization.

### Additive Manufacturing

Additive manufacturing is a three-dimensional material dispositioning, typically layer by layer. One type of additive manufacturing is 3D printing. Additive manufacturing is considered a low-cost and scalable technology that allows the production of complex shapes and geometries such as hollow shapes that are hard to produce by other manufacturing methods. Additive manufacturing is compatible with a large variety of materials, including polymers⁷², metals⁷³, ceramics⁷⁴, biological materials⁷⁵, and more.

In recent years, different strategies for 3D printing of LHP materials have been demonstrated. Chen et al. developed a 3D printing process based on guiding evaporation-induced perovskite crystallization for organic-inorganic halide perovskites⁷⁶. The crystallization occurred at a confined femtoliter ink meniscus, and its continuous guiding process enabled nanoscale 3D printing. This procedure resulted in freestanding 3D perovskite nanostructures with a preferred crystal orientation.

Another in situ example was demonstrated by Huang et al. that showed reversible 3D laser printing of CsPbBr₃ QDs inside a transparent glass medium⁷⁷. This method utilized the low formation energy of perovskites to produce many cycles of writing and erasing LHP QDs patterns on-demand, using femtosecond laser irradiation and thermal annealing.

Another approach for 3D printing of LHP is by printing already synthesized nanocrystals encapsulated in polymer solutions. In this approach, the crystals are prepared in traditional synthesis methods and mixed into a polymer and solvent solution. This method takes advantage of the polymers' transparency, flexibility, and compatibility with 3D-printing technologies without affecting the bond structure of the polymer⁷⁸. This method allows producing a variety of shapes while preserving the high PL of the nanocrystals and improving their stability due to the polymer encapsulation.

While most optical properties are determined prior to the printing itself, some can be affected by the printing process. Such an example was demonstrated by Zhou et al., who showed control over the polarization of CsPbBr₃ nanowires suspended in a polystyrenepolyisoprene-polystyrene block copolymer matrix by the direction of printing⁷⁹. The nanowire alignment was defined by the printing direction due to the shear stress-induced during the ink extrusion, resulting in highly polarized absorption and emission properties.

### Optical Waveguides

An optical waveguide is a structure that confines and directs propagating electromagnetic waves in the optical spectrum. Optical waveguides can be classified according to their geometry, where the basic structure contains material with a high refractive index where light is confined (“core”) than its surrounding (“cladding”). The simplest waveguide example is a planar waveguide in which only a single dimension is restricted, and propagation is permitted in two dimensions. However, most waveguides, such as channel waveguides and optical fibers, are restricted to two-dimensions aod form one dimensional elongated waveguides where propagation is permitted only in one dimension⁸¹ (FIGS. 3A-C).

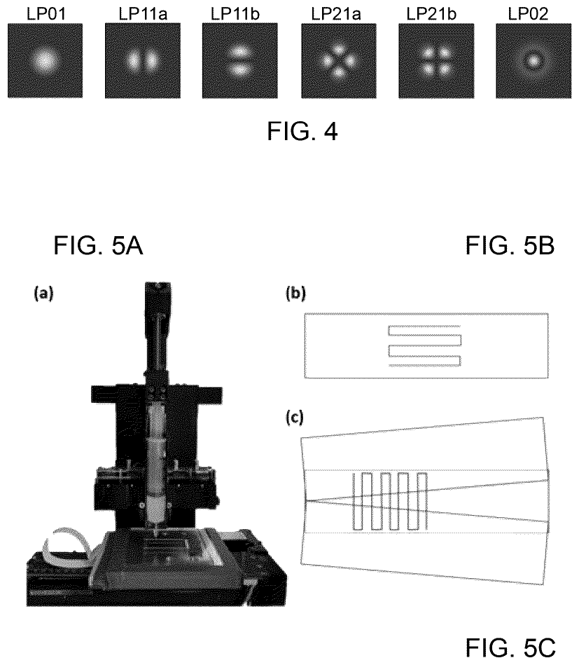

The basic principles behind optical waveguides can be explained using ray optics principles. When light encounters an interface of a material with a lower refractive index, it can be trapped and guided due to a total internal reflection. However, the full description of optical waveguides can be solved by Maxwell's equations using analytical or numerical methods. This approach considers the propagation and interference of light waves that create electromagnetic interference patterns called modes, as shown in FIG. 4. A waveguide may guide only a single mode (single-mode waveguide)⁸², or many guided modes (multimode waveguides)⁸³. The number of guided modes and the guided wavelengths are determined by the geometry and refractive indices of the waveguide.

Optical waveguides most commonly consist of glass or polymer core, with or without cladding material⁸⁴. They can be used for different applications such as integrated optical circuits⁸⁵ and short or long-distance optical fiber communication⁸⁶.

Several attempts have been made to incorporate LHP QDs into waveguides. Chen et al. developed a process in which LHP nanocrystals were spontaneously formed on the surface of CsPb₂Br₅ nanowire waveguides⁸⁷. Other researches utilized the high refractive index and transparency of polymers to incorporate LHP nanocrystals into polymer waveguides⁸⁸. The Inventors appreciate that these attempts are not sufficient as since the technologies that they employed require the emission of single photons. Coupling of a single perovskite QD with a tapered optical nanofiber was also demonstrated⁸⁹, however the Inventors found that this attempt suffers from low stability of non-encapsulated QDs and lack of scalability due to the complexity of the method, which requires a manual operation of a translation stage under a microscope.

### EXPERIMENTAL

### List of Materials

Acetone (A. R., Aldrich), benzoyl bromide (97%, Aldrich), cesium carbonate (Cs₂CO₃, 99.9%, Aldrich), 2-propanol (A. R., Bio-Lab ltd.), lead acetate trihydrate (99.99%, Aldrich), methyl alcohol, anhydrous (HPLC, Macron Fine Chemicals), octadecene (ODE, 90%, Aldrich), oleic acid (OA, 90%, Aldrich), oleylamine (OLA, 70%, Aldrich), Polymethyl methacrylate powder (PMMA, Alfa Aesar), toluene (A. R., Aldrich). All chemicals were used as purchased without further purification.

### Synthesis

CsPbBr₃ perovskite QDs were synthesized following Imran et al. synthesis protocol⁹⁰.

16 mg of cesium carbonate, 7 mg of lead acetate trihydrate, 0.3 ml of oleic acid (OA), 1 ml of oleylamine (OLAM) and 5 ml of octadecene (ODE) were loaded into a 25 ml 3-neck flask and dried under vacuum at 100° C. for 1 hour. Then, the temperature was increased to 180° C. under N₂ and 78 μl of benzoyl bromide was quickly injected into the reaction. The reaction was then immediately cooled down using an ice-water bath. Then 5 ml of toluene was added to the solution, and the resulting solution was centrifuged for 10 min at 4 krpm. The precipitate was redispersed in 5 ml of toluene. Then, a second centrifuge was done for 5 min at 8 krpm to eliminate larger particles.

### Sample Preparation

### Solution Preparation:

20% wt PMMA in toluene solution was made using the following steps: 2.18 gr of PMMA was added to 10 ml of toluene. The mixture was mixed overnight using a magnetic stirrer at 50° C. Then the temperature was decreased to room temperature, and the solution was kept on stirring until it was entirely homogeneous.

200 μl of 1:100 diluted QDs solution in toluene was added slowly to the PMMA solution while the PMMA solution was mixed on a vortex mixer. Then the resulting solution was mixed for an additional 2 min on the vortex mixer to ensure optimal dispersion of the QDs in the solution. Then, the mixture was vacuumed to eliminate bubbles.

### 3D Printing:

The QDs—PMMA solution was loaded into a 30 cc BD syringe with a blunt 27G needle. The syringe was then placed on an SDS-30 printing head on our Hyrel Engine HR 3D printer. Two types of samples were prepared using 3D-printing, as demonstrated in FIGS. 5B-C.

Printed polymer filaments: 5 straight 2 cm perpendicular lines were printed on glass, silicon or round 1″ coverslip substrates (FIG. 5B). The silicon substrate was cut into approximately 1.5×3 cm pieces and washed in acetone, methanol and isopropanol using an ultrasonic sonicator for 5 min for each solvent. Then the substrates were dried under N₂. The coverslips were rinsed in toluene, then washed in acetone and isopropanol using an ultrasonic sonicator for 5 min for each solvent and dried under N₂.

The printing parameters are controlled by the G-code that includes all the commands for the movement of the 3D printer. The chosen printing parameters for these samples were: 1.0 flow multiplier⁹¹, 77 pulses per microliter of the motor, 0.1 mm width, 0.1 mm layer thickness and 5000 mm/min⁹² speed.

Suspended polymer fibers: Two microscope slides were attached to another slide, leaving a 1-2 mm gap between the two slides (FIG. 5C). Then, parallel lines were printed on the top of this structure, creating thin suspended fibers in the gap between the two slides. Then, the fibers were carefully collected with a silicon or glass piece of approximately 1 mm×4 mm size. The silicon/glass was slowly moved along the gap between the two microscope slides to harvest the fibers. The chosen printing parameters for these samples were: 1.0 flow multiplier⁹¹, 77 pulses per microliter of the motor, 0.1 mm width, 0.1 mm layer thickness and 1000 mm/min⁹² speed.

### Characterization Methods

### Absorption and Emission Measurements:

Optical measurements were performed using a Synergy H1 hybrid multi-mode reader with a xenon lamp (Xe900) irradiation source. 5 μl of the QDs solution was added to a quartz cuvette with 4 ml toluene. The emission was measured for a 370 nm excitation wavelength

### Transmission Electron Microscopy (TEM):

The size, shape and size dispersion of the QDs were studied using TEM. TEM micrographs were recorded using TEM mode with 200 KV FEI Tecani G2 T20 S-twin LaB6 TEM, with 1K×1K Gatan 694 rectangular slow-scan CCD. The sample was made by drop-casting QDs diluted solution on a carbon grid.

### X-Ray Diffraction (XRD) Analysis:

The QDs crystalline structure was determined by XRD analysis using a Rigaku Smart-Lab 9 kW high-resolution X-ray diffractometer, equipped with a rotating anode X-ray source Using theta-2theta mode, with radiation wavelength of λ=1.5418 Å (Cu Kα). The sample was made by precipitating the QDs from the solution using a centrifuge and placing them on a microscope slide.

### Optical Microscopy.

The width of the printed filaments was measured using optical microscopy. Olympus BX51 Light Microscope was used with a CCD digital camera (CAM-SC30) and 5×, 10× objectives.

### Scanning Confocal Fluorescence Microscopy:

The distribution and the emission spectra of the QDs in the printed filaments were studied using scanning confocal fluorescence microscopy. The scans were performed using WITec alpha300R Confocal Raman Microscope, with Zeiss optical microscope equipped with an LED white-light source, spectrometer UHTS600 with 300, 1200, 2400 gr/mm gratings, and a back-illuminated CCD camera (Andor IDUS series). 457 nm laser source was used with two objective lenses: Zeiss EC Epiplan-Neofluar Dic 50×/0.8 and Zeiss EC Epiplan-Neofluar Dic 100×/0.9. The integration time and laser power are specified for each scan.

The samples were printed on a silicon substrate for these measurements.

### Fluorescence Microscopy:

Fluorescence microscopy was used in order to study the light propagation in the suspended fibers. The samples were placed in an optical microscope (Nikon, eclipse Ni—U upright microscope) and excited with a 450W ozone-free xenon arc lamp at 370 nm wavelength. The emitted light was collected through an objective lens (Nikon, Plan Fluor 10×/0.30, Nikon, Plan Fluor 40×/0.75) and directed into a CCD camera (DFK 23UP031) after passing a 404 nm long-pass filter to eliminate the excitation light.

### Ploy Measurement:

PLQY of the encapsulated QDs and non-encapsulated QDs was measured using a Photoluminescence spectrometer (FLS1000, Edinburgh instruments). The samples were placed in an Integrating sphere (N-M01, Edinburgh instruments) and excited with a 450 W ozone-free xenon arc lamp at 370 nm wavelength. For the encapsulated sample, 40 μl of QDs solution was added to a quartz cuvette with 4 ml of 20% wt PMMA in toluene solution. For the non-encapsulated sample, 40 μl of QDs solution was added to a quartz cuvette with 4 ml of toluene.

### High-Resolution Scanning Electron Microscopy (HRSEM):

HRSEM micrographs were recorded to study the shape of the suspended fibers, using SEM microscope model Zeiss Ultra-Plus HRSEM. Samples were placed at a working distance of 3.1 mm and measured using secondary electrons signal with an acceleration voltage of 0.7 KV. Silicon substrate was used for the studied samples.

### Results and Discussion

### Characterization of CsPbBr₃ ODs

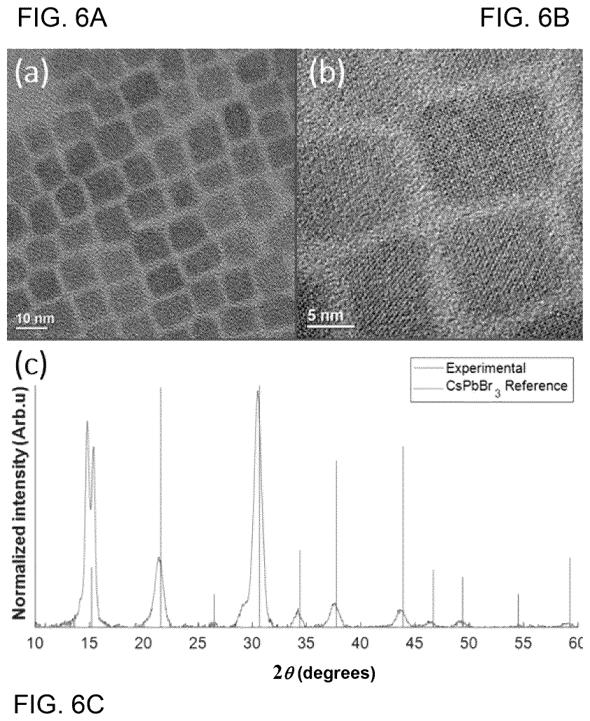

In order to confirm the formation of QDs and determine their structure, a diluted solution of CsPbBr₃ QDs was drop casted on a carbon grid and was inspected using TEM. TEM micrograph in FIG. 6A shows the cube structure of the QDs with about 10 nm edge length and narrow size dispersion. Approximately uniform distance between adjacent NCs is observed and attributed to the presence of ligands on the QDs' surface. FIG. 6B shows a high-resolution TEM (HRTEM) micrograph, reviling the atomic planes of the perovskite QDs. XRD pattern of precipitated QDs solution (FIG. 6C) showed agreement with a cubic perovskite structure. The origin of the additional peak at 150 is attributed to a contamination of the sample.

### Optical Properties

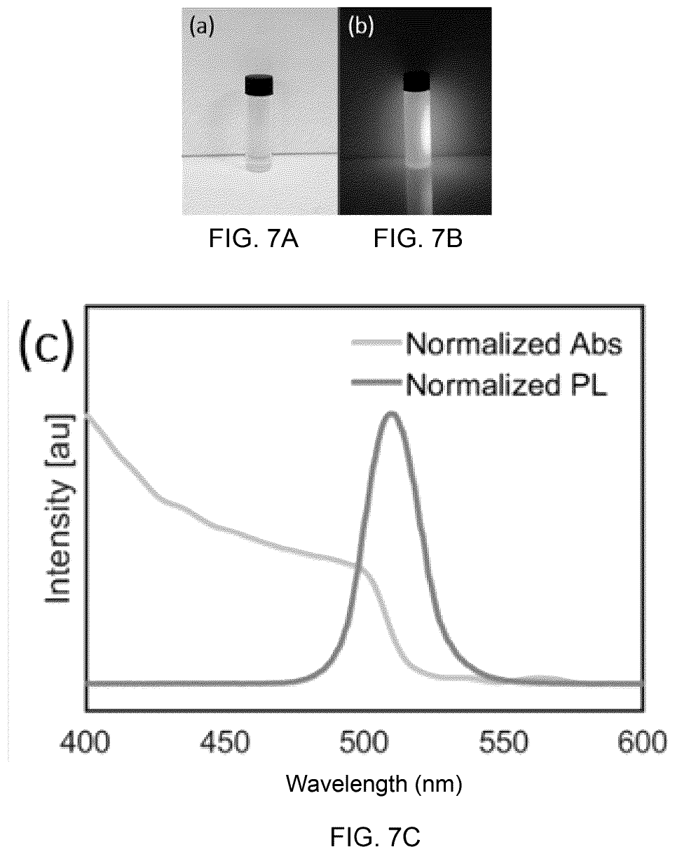

FIGS. 7A and 7B shows images of post-synthesized QDs solution under ambient light and UV light, respectively. Bright green photoluminescence light is observed under UV excitation, indicating the success of the synthetic process. Absorption and emission intensities of diluted QDs were then measured using a spectrometer (FIG. 7C). As typical for excitonic emission, a narrow peak emission is noticed around 510 nm. The emission wavelength is blue-shifted relatively to the bulk CsPbBr₃ structure⁹⁷, in agreement with quantum confined excitonic emission⁵.

### ODs in Polymer Printed Samples

Polymer encapsulation of QDs is widely used to increase QDs stability under humidity and laser excitation⁴¹. The most common method for fabricating single QDs samples is by spin coating a diluted solution of QDs with a low polymer concentration, such as PMMA⁵³ or PS⁵⁷. This method showed its ability to effectively protect the QDs from contact with the environment while preventing the agglomeration of the NCs so they can serve as SPS. However, in order to achieve an integrated QD in a photonic device for quantum technologies-oriented applications, some challenges need to be addressed. Some of these challenges are the lack of accuracy in positioning the single QD, the difficulty of coupling it into a device, and the limited scalability. We aim to address these challenges, while maintaining the benefit of increased stability, by developing a 3D-printing sample preparation procedure of single CsPbBr₃ QDs encapsulated in PMMA.

This Example demonstrates that the printed filaments of the present embodiments serve as waveguides for the emission of the encapsulated QDs. This Example demonstrates that the encapsulated QDs are single QDs that act as SPS, and the increased stability of the encapsulated QDs compared to non-encapsulated QDs.

### Engineering Printed Filaments

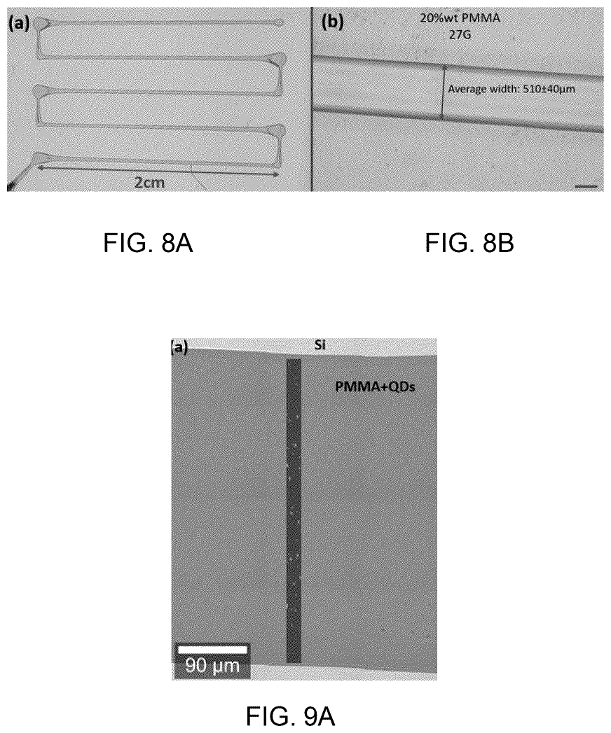

A simple design of 5 parallel printed lines on a glass substrate was chosen for our samples, as shown in FIG. 8A.

In order to study the effect of 3D printing parameters on the width of the printed filaments, we conducted a series of printing experiments of PMMA solution in toluene without NCs. The examined parameters can be separated into two groups: exterior parameters, including the polymer concentration and printing needle diameter, and mechanical parameters determined by the G-code that controls the movement of the 3D printer. These mechanical parameters include the printing speed, flow multiplier, number of pulses per microliter, width of the cross-section of the volume to fill, and the height of the cross-section of the volume to fill. A more in-depth explanation of the mechanical parameters can be found in ref. [91].

For each examined parameter, the width of the sample was measured for each of the five parallel lines (FIG. 8B) using optical microscopy, and the average value and standard deviation were calculated.

It was found that only the exterior parameters showed a noticeable effect on the filament width. Tables 1 and 2 present the results for different needle diameters and polymer concentrations, respectively.

TABLE 1
Average filament width for different PMMA concentrations.

| Polymer concentration [% wt] | Filament average width |
|---|---|
| 15 | 530 ± 40 |
| 20 | 510 ± 40 |
| 25 | 170 ± 30 |

TABLE 2
Average filament width for different printing needle diameters.

| | Needle inner | Filament average |
|---|---|---|
| Needle gauge | diameter [μm] | width [μm] |
| 24G | 320 | 630 ± 30 |
| 26G | 260 | 470 ± 20 |
| 27G | 200 | 510 ± 40 |
| 32G | 100 | 240 ± 5 |

As shown in Table 1, a higher polymer concentration led to thinner filaments since the increase in concentration caused higher viscosity of the solution so less material was extruded by the printer. 20% wt PMMA was chosen as the concentration in this Example. Higher concentration (e.g., 25% wt PMMA) was not used due to the high viscosity of the solution.

Table 2 summarizes the effect of the inner needle diameter on the printed filaments' width. 27G needle was chosen for this Example since a 32G needle was intermittently plugged.

The printing parameters showed no significant effect on the filament width, except inconsistent height calibration and toluene evaporation during the printing.

### Homogeneous Distribution and Emission of ODs in Filaments

A diluted solution of QDs was incorporated into the polymer solution following the procedure specified in the methods section above, and the obtained mixture was printed on a silicon substrate.

The distribution of the QDs inside the PMMA filaments was studied using scanning confocal fluorescence microscopy. Using this method, a desired area of the sample is scanned, and a PL spectrum of each scanned pixel is measured. Further data processing allows displaying a color-coded map of the scanned area.

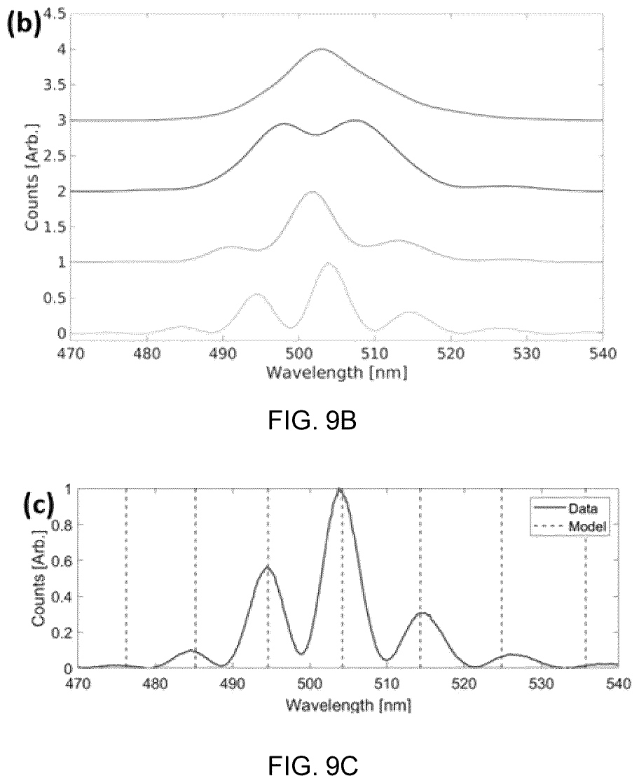

FIG. 9A presents an optical image of the printed sample on a silicon substrate, where the dark rectangle corresponds to the scanned area, and the bright spots indicate the presence of QDs discovered by the fluorescence microscopy scan. The scanning was performed using a 457 nm excitation laser at 0.3 mW laser power and an integration time of 0.05 s. Random distribution of the QDs inside the filament is received, indicating an efficient mixing of the QDs in the printing solution. The spectra of the detected QDs are shown in FIG. 9B. The red spectrum corresponds to a standard CsPbBr₃ QD, while the other spectra show periodic modulation of the emission intensity. A possible explanation for this modulation is a formation of a standing wave of the emitted light inside the PMMA layer.

When reaching the interface between the PMMA and the air/silicon, a fraction of the emitted light from the QDs is reflected back according to Fresnel's equations. The light may reflect multiple times inside the printed layer and produce standing waves for specific resonance frequencies, called modes.

The length of the layer in which the standing wave is formed (the thickness of the printed PMMA layer) can be calculated from the condition for standing wave formation:

$$L = m \frac{{λ}_{m}}{2 n} \qquad ( 3 )$$

where m is the mode number, λₘ is the wavelength in free space and n is the refractive index.

By choosing two adjacent modes from one of the measured spectra, two equations are obtained and can be easily solved. The calculated value for the PMMA thickness was found to be L=8.6 μm.

The calculated thickness was inserted back into equation (3) to obtain all the calculated wavelengths which can form a standing wave inside the PMMA layer. FIG. 9C presents a decent fit of the emission spectrum peaks to the theoretical wavelengths.

To measure the layer thickness experimentally and find the distribution of the QDs in the cross-section of the filament, a similar sample was broken into two pieces and studied using the scanning confocal fluorescence microscopy method. The scanning was performed using a 457 nm excitation laser at 0.1 mW laser power and an integration time of 0.1 s.

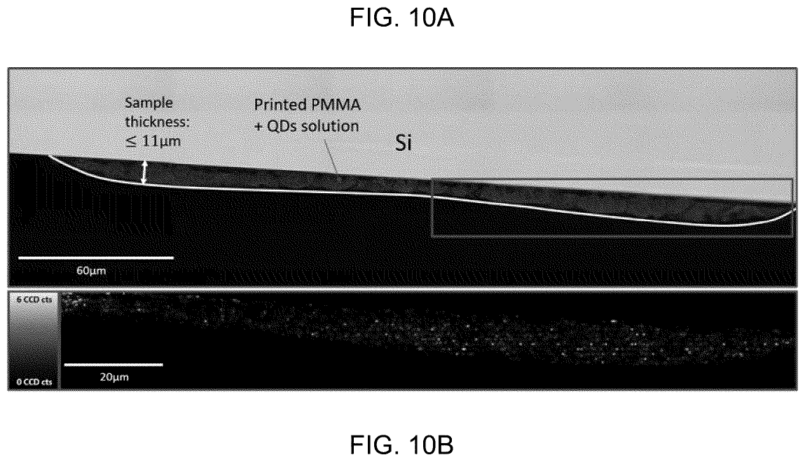

FIG. 10A presents an optical image of the cross-section of the printed filament. The marked area represents the PMMA/air interface and the red rectangle defines the scanned area. The optical image reveals an ununiform layer thickness profile, with a maximum thickness of around 11 μm. This result agrees with the layer thickness calculation and, consequently, supports the notion of a standing wave in the printed filament. A scanning confocal fluorescence microscopy image of the filament is presented in FIG. 10B, showing a random distribution of the QDs in the cross-section.

### Simulating Light Guiding in Waveguides

The discovery of standing waves of the emitted light inside the PMMA filaments allowed the Inventers to induce additional photonic effects in the samples of the present embodiments and to utilize those effects to improve SPS.

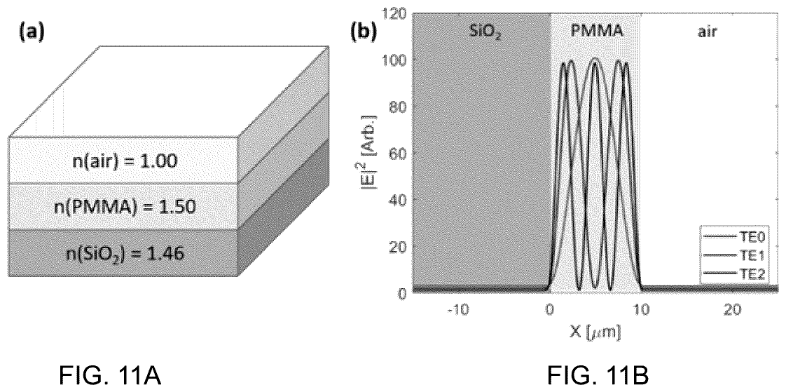

FIG. 11A is a simplified schematic illustration of the cross-section of the printed filament and points out the refractive indices of the PMMA layer and the adjacent mediums¹⁰⁹. The refractive indexes correspond along a wavelength of 510 nm, representing the emission wavelength of the QDs. The substrate's refractive index corresponds to native silicon oxide since whenever a silicon wafer is exposed to air under ambient conditions, a thin layer of SiO₂ is formed. This structure, where the middle layer has a high refractive index compared to the adjacent layers, can serve as a waveguide for certain wavelengths depending on its dimensions.

In order to determine whether the printed filament can serve as a waveguide for the emitted light of the QDs, a waveguide simulation⁹³ was conducted with parameters specified in the methods section, above. The simulation detected all the electromagnetic modes that are supported by the simulated waveguide by solving Maxwell's equations analytically with the appropriate boundary conditions.

FIG. 11B shows the intensity of the electric field for the first three modes supported by the waveguide, extracted from the waveguide simulation. The simulation demonstrates that the electric field is confined to the PMMA layer and the presence of supported modes confirms that the printed filament act as a waveguide for the emitted light from the QDs. This demonstration of the waveguiding property of the printed filaments is a promising step toward integrating CsPbBr₃ emitted light into photon-based devices, aiming for integrated SPS for future quantum applications.

### Single QDs Measurements

Since the scanning confocal fluorescence microscopy is limited by the optical resolution limit, single QDs and clusters of QDs smaller than the diffraction limit cannot be distinguished. The HBT experiment was therefore used to distinguish between single QDs and clusters.

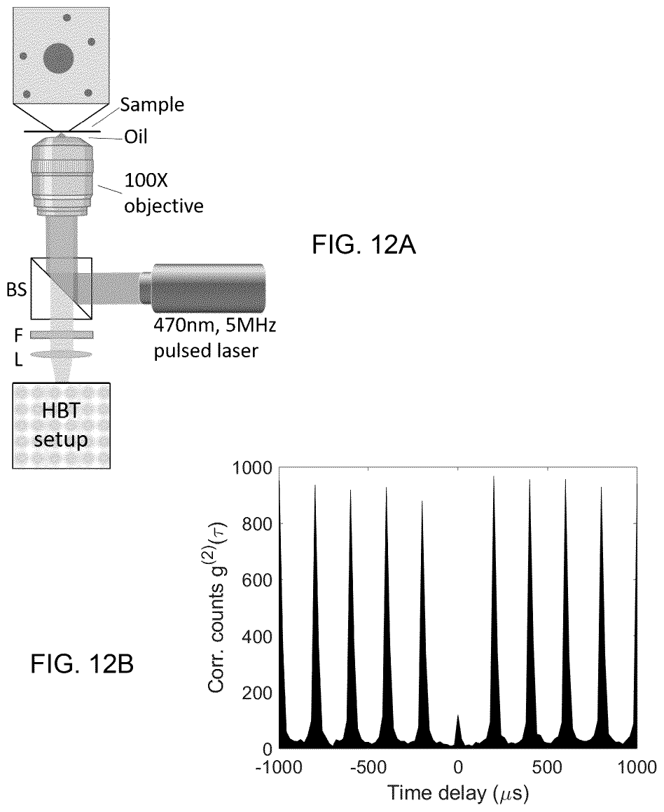

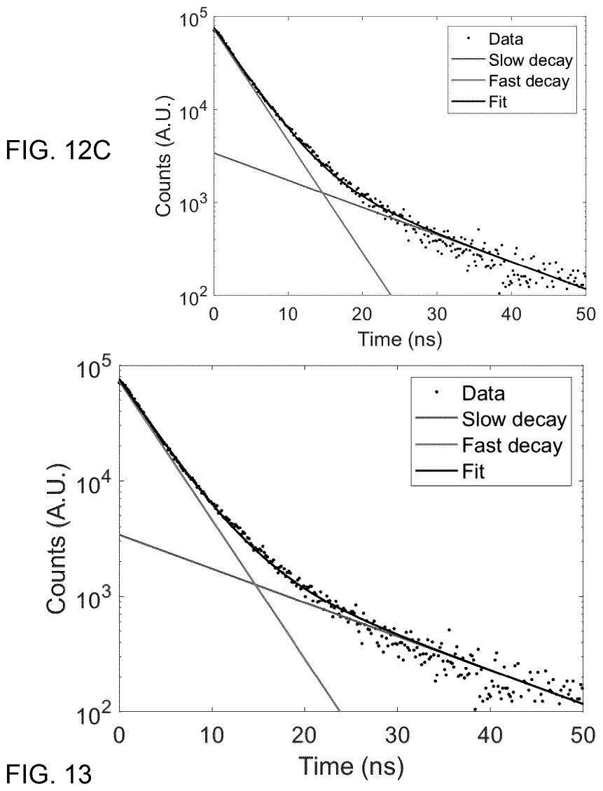

FIG. 12A is a schematic illustration of the single QDs measurements setup. Confocal mode: only one QD is measured and the PL emission is directed into an HBT setup. FIG. 12B shows measured second order correlation function. The normalized g₂(0) value was calculated for 22 individual QDs and found to be 22±14%, indicating single photon emission. FIG. 12C shows lifetime measurement demonstrating two exponential decay rates. The average decay rates for the measured QDs was 1.6±0.4 ns for the fast decay, indicative of trions or biexcitons, and 10±2 ns for the slow decay rate, indicative of excitons.

A printed PMMA/QDs filament was excited under a 470 nm pulsed laser with a 5 MHz repetition rate. Fluorescence intermittency, or blinking behavior, was apparent from the random switching between “on” and “off” emission states. This behavior was observed for the vast majority of excited QDs while examined in the widefield mode of the optical setup, where many QDs are illuminated simultaneously, and the emission is directed into a CCD camera. It is known that clusters and bulk materials do not show fluorescence intermittency, and therefore, the observation of blinking behavior is considered as an indication of the presence of single QDs.

To confirm the presence of single QDs and their ability to emit single photons, HBT experiment was conducted for random QDs found in the sample. High peaks of the g₂(τ) function were observed at 200 μs delay time intervals, in accordance with the time between the laser pulses. In addition, a low peak at zero-time delay was observed, indicating the lack of correlation between photons arriving simultaneously hence a low probability of measuring two photons at the same time. This probability was calculated for 22 different individual QDs by dividing the zero-time delay peak by the average of the other peaks. The calculated probability was found to be 22±14%, which is lower than 50% and therefore considered as a confirmation for a SPS¹⁷. This result demonstrates the ability of the present embodiments to separate the QDs through the sample preparation method. This result confirms the single-photon emission nature of single CsPbBr₃ QDs.

As the time of each photon detected during the experiment is recorded, radiative lifetime measurements can be extracted from the same data that was used for the construction of the g₂(τ) function. FIG. 13 shows an example of a lifetime analysis for one of the measured QDs. The discrete points are the measured data, the red and blue lines represent fitted functions of fast and slow exponential decay rates, respectively, and the black line is their summation. The average fast and slow decay rates were extracted for 20 measured single QDs. The average slow decay rate of 10±2 ns is attributed to excitonic decay, while the rapid decay rate of 1.6±0.4 ns is attributed to the recombination of trions and biexcitons¹¹⁰. Compared to other commonly researched QDs such as CdSe QDs¹¹¹, the measured excitonic decay rate of the present embodiments is faster, and therefore advantageous for quantum computation applications as it can lead to faster calculation rates.

### Fluorescent Stability and Encapsulation

The same setup used for the single QDs measurements was also used to compare the photostability of the CsPbBr₃ QDs with and without PMMA encapsulation. A non-encapsulated QDs sample was prepared by drop-casting a diluted solution on a glass coverslip in addition to our standard 3D printed sample. The samples were excited by a pulsed 470 nm laser with a 5 MHz repetition rate and 200 nW intensity, and the resulting emission intensity was recorded as a function of time. The intensity was purposely chosen so that degradation could be seen within a few minutes so that the experiment time would be reasonable. By multiplying the time scale by the laser repetition rate, the scale was replaced with the number of laser pulses which can be referred to as the number of excitation cycles of the QD⁴¹.

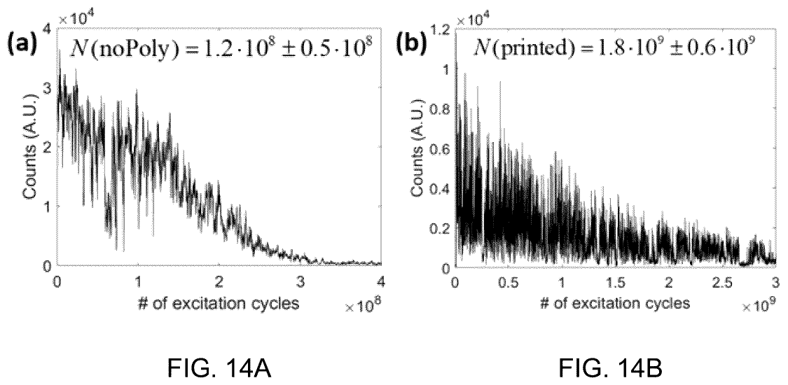

FIGS. 14A and 14B present examples of the intensity as a function of the number of excitation cycles for non-encapsulated QD compared to a printed QD. For both, fluorescent blinking is obvious and a rapid intensity reduction is present, indicating a photobleaching process. In order to eliminate the effect of the fluorescent blinking, the data was smoothed and the number of excitation cycles until the intensity decreased by an exponential factor was extracted. The number of excitation cycles before degradation was measured for nine non-encapsulated QDs and 8 printed QDs and the mean value was calculated and the values of N(noPoly)=(1.2±0.5)·10⁸ and N(printed)=(1.8±0.6)·10⁹ were obtained. As shown, the polymer encapsulation increased the number of excitation cycles of the encapsulated sample by a factor of 15.

This result demonstrates the advantage of the 3D printing method for single QDs sample preparation. It allows control over the shape and position, and also reduces degradation significantly.

PLQY measurements were performed to investigate a decrease in the average emission intensity by about 50%. The PLQY measurements were performed using an integrating sphere for QD solution with and without PMMA. PLQY values of 53±2 and 38±2 were found for the QDs without PMMA and the QDs in the polymer solution, respectively. The error for these measurements was measured by running the measurement for a reference solution five times and calculating the standard deviation.

Performing the measurements for the solution form of the samples is advantageous for two main reasons. Firstly, it allows having better statistics since it measures the emission from numerous QDs. Secondly, it enables to determine whether this decrease in the intensity was caused by the polymer encapsulation itself or by the 3D printing process. Since the decrease in PLQY is present regardless of the printing process, it is concluded that the polymer encapsulation itself causes it. This decrease is assumed to be caused by the mixing process and the contact of the QDs with polymer molecules which may lead to a separation of ligands from the QDs' surface and induce degradations.

### QDs in Suspended Polymer Fibers

The present Inventors successfully achieved high resolution of the position of the single QDs, wherein a single QD was placed on a single target pixel. This Example demonstrates a method for 3D-printing of suspended PMMA fibers with encapsulated single CsPbBr₃ that allows to improve the QDs placement resolution by up to three orders of magnitude. The following description presents optical images that reveal the geometry of the fibers, and studies the distribution of the QDs inside the suspended fibers and their emission spectra. The propagation of light inside the fibers is discussed and their ability to act as optical fibers for the emitted light from the QDs is demonstrated using an optical fibers simulation.

### Studying the Distribution and Emission of ODs in Polymer Fibers

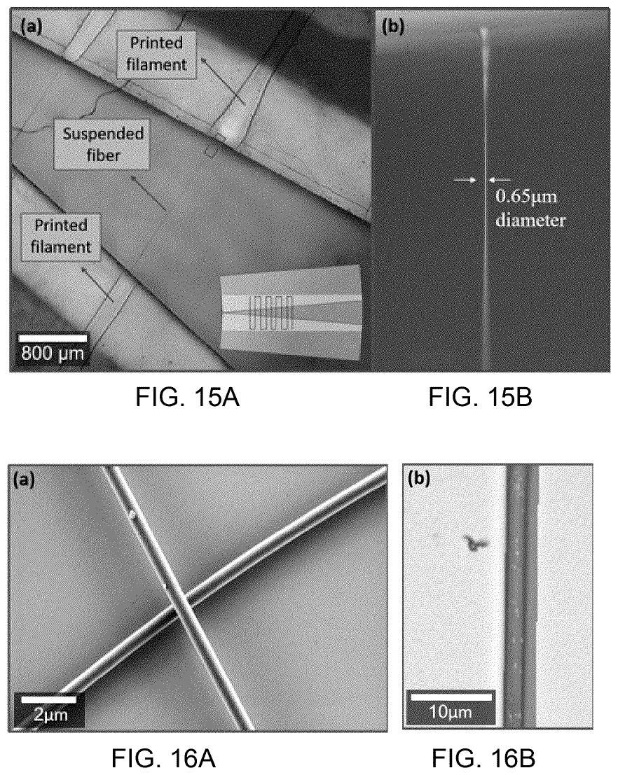

Following the sample printing procedure specified in the method section above, suspended fibers were created by printing PMMA/QDs solution on a pre-made substrate where two slides with a varying gap between them were attached on top of an additional slide, as illustrated in the inset of FIG. 15A.

As shown in FIG. 15A, the printed filaments of the present embodiments were formed on the two top glass slides, where the printing needle contacted the substrate. Thin suspended fibers were formed in the gap between the slides, as shown in the zoomed-in optical image of FIG. 15B. The length of the obtained fibers can be controlled by changing the distance between the slides. The fibers diameter was not affected by controllable parameters and ranged between 0.5-10 μm, demonstrating a reduction of 2 to 3 orders of magnitude relative to the width of samples obtained with standard printing, and leading to significantly better resolution of the QDs positioning.

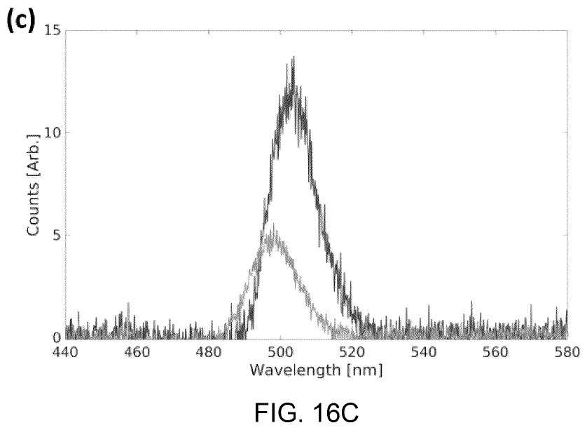

After printing, the fibers were transferred into a silicon substrate by sliding a ≈1 mm wide silicon piece between the two glass slides, where the fibers were formed. To find the distribution of QDs inside the suspended fibers, few fibers were scanned using HRSEM. While QDs were not detected by this method, it produced high resolution micrographs of the fibers where their cylindrical shape can be clearly seen (FIG. 16A).

Using scanning confocal fluorescence microscopy, a similar sample was scanned to find the distribution of QDs and their emission spectra. The scanning was performed using a 457 nm excitation laser at 0.5 mW laser power and an integration time of 0.05 s. FIG. 16B presents an optical image of a scanned fiber where the red and green points indicate the presence of QD according to the emission spectra shown in FIG. 16C. The QDs are randomly distributed in the PMMA fiber and show standard emission spectra corresponding to the QDs solution spectrum.

### Fluorescence Microscopy of Highly Concentrated Samples

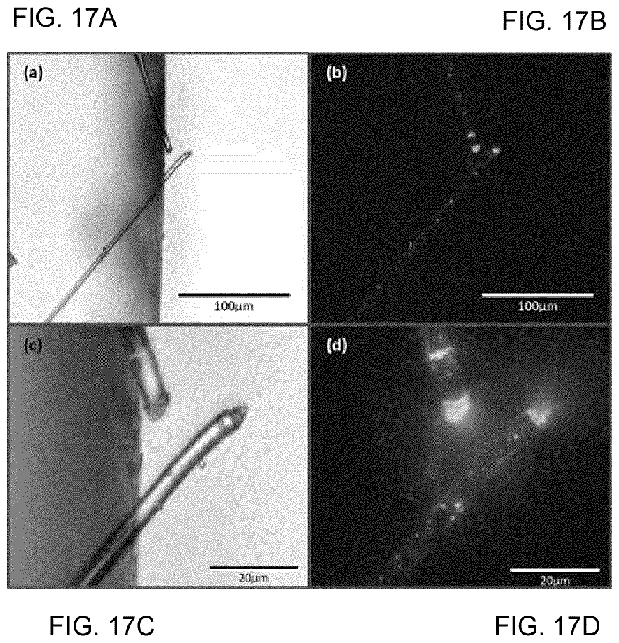

To study the propagation of light in the PMMA fibers, highly concentrated QDs/PMMA fibers were prepared using the same procedure as specified in the methods section, above, except that for this study the PMMA printing solution contained 200 μl of the original QDs solution, instead of diluted QDs solution. FIGS. 17A and 17C present optical images of a PMMA/QDs fiber that was broken into two pieces while collecting it with a glass substrate. FIGS. 17B and 17D presents the same fibers under UV excitation at 370 nm wavelength. Many bright spots are observed inside the fibers, indicating the presence of clusters of QDs. More interestingly, intense illumination at the edges of the fibers can be seen. This observation strongly indicates that some of the light emitted from the QDs travels along the PMMA fibers and is scattered through their edges.

### Ray Optics Simulation

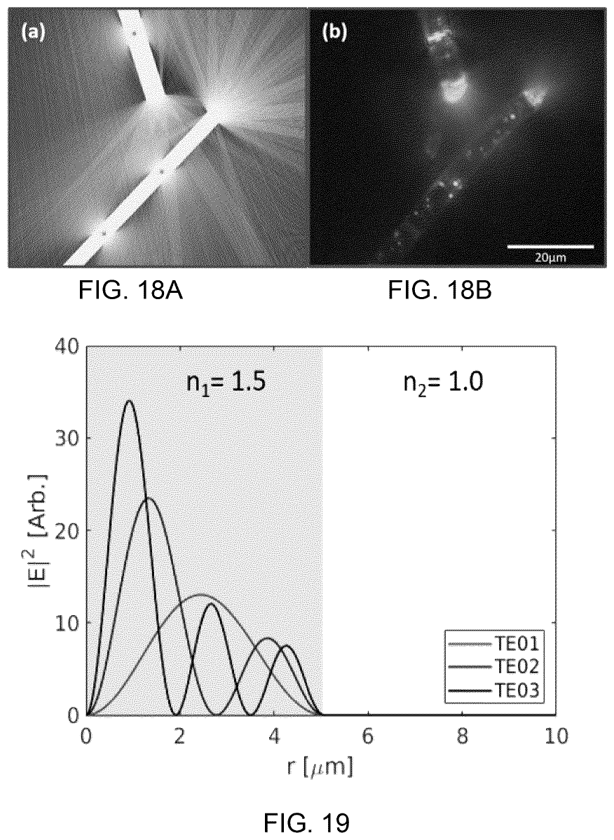

FIGS. 18A and 18B present the resulting simulation compared to the experimental optical image of PMMA/QDs fibers illuminated with a UV light. A strong resemblance is shown between the two images. The simulation predicts some light rays transmitted through the fiber/air interface. This is evident experimentally by the bright emission spots inside the PMMA fibers, since they originated from the QDs' emission that transmitted through the PMMA/air interface and went straight into the camera. A higher light-rays concentration is scattered through the fibers' edge in the simulation, and is seen as the bright illumination at the edges of the fibers experimentally. This explains the difficulty of measuring single photons emitted from single QDs inside the fibers. Since most photons travel along the PMMA fibers and are scattered through the edge, fewer photons reach the detectors, so the emission intensity appears to be lower to the point where they cannot be measured.

### Simulating Light Guiding in Optical Fibers

While the 2D ray optics simulation does not take into consideration the geometry of the fibers and the emission wavelength. To determine whether the suspended PMMA fibers of the present embodiments can serve as an optical fiber for the emitted light from the QDs, an optical fiber simulation⁹⁶ was conducted for parameters as specified in the methods section, above. The simulation detected all the electromagnetic modes that are supported by the simulated optical fiber by solving Maxwell's equations analytically with the appropriate boundary conditions⁹⁴. FIG. 19 shows the intensity of the electric field as a function of distance from the center of the fiber for the first three modes supported by the optical fiber. The existence of supported modes confirms that the suspended fibers act as optical fibers for the emitted light from the QDs. In this example, a diameter of 10 μm was simulated, but similar results were obtained for fibers with smaller diameters, up to a diameter of 0.2 μm.

Electrospinning of Polymeric Fibers Loaded with CsPbBr₃ Emitters

Electrospinning is a fiber production method that uses electric force to draw charged threads of polymer solutions or polymer melts up to fiber diameters in the order of some hundred nanometers. Electrospinning shares characteristics of both electrospraying and conventional solution dry spinning of fibers. The process does not require the use of coagulation chemistry or high temperatures to produce solid threads from the solution. This makes the process particularly suited to the production of fibers using large and complex molecules and integrated QDs such as CsPbBr₃ or other compositions.

This Example demonstrated a wet processing method for single CsPbBr₃ QDs encapsulated in polymer self-drawn fibers that serve as light guides for single-photon QD sources. The fibers can be self-drawn by three-dimensional, electrospinning, extrusion or the like.

The fabrication method developed for perovskite-based SPS has an advantage over the standard spin-coating procedure because of the combination of the micrometer placement resolution of the QDs, the reduced photobleaching thanks to the polymer encapsulation, and the ability of the suspended fibers to serve as optical fibers for single photons emitted from the QDs. The CsPbBr₃ emitted light can be integrated into photon-based devices and be used in quantum applications on-a-chip devices in photonic circuits for quantum communication applications.

### Example 2

Quantum dots of metal halide perovskites for single photon emission are known to have insufficient structural stability, and insufficient long-term efficiency. The most prevalent of these defects would arise on the surface as Shockley-Read-Hall shallow trapped states, typically in the form of lead or bromide deficiencies¹¹². These traps decrease the photoluminescence quantum yield of the nanocrystals, by introducing fast non-radiative recombination pathways. Surface treatment using pseudohalides was effective for standard semiconductors of different chemistries¹¹³ Specifically thiocyanate has been demonstrated in the past as a successful agent for use in the passivation of II-VI nanocrystals and recently in perovskite solar cells and nanocrystals¹¹⁴⁻¹¹⁶. It improves quantum yield drastically while maintaining structure and morphology.

Attempts have been made to use benzoyl halides as halide sources to be injected in a solution of metal cations for the synthesis of APbX₃ NCs¹²¹.

In this Example, the efficiency and stability increase of thiocyanate is utilized as a surface treatment for single photon emitters. Thiocyanate binds to bromine vacancies on the surfaces, fulfilling those traps, subsequently increasing PLQY and ambient stability^{119,110}. The ionic liquid urea ammonium thiocyanate (UAT) allows studying thiocyanate's influence on surface binding through a variety of spectroscopic techniques while simultaneously improving the quality of their surfaces. However, the Inventors found that conventional procedures are not without certain limitations that would best be avoided.

In this Example, an ionic liquid of thiocyanate is utilized allowing to establish a scalable process for the passivation of single photon perovskite emitters. The solubility of thiocyanate was enhanced by working at the liquid-liquid interface of UAT and the CsPbBr₃ nanocrystal colloid. This technique is advantageous over conventional techniques since it allows scaling better characterization of resulting products, high PLQY QDs, that are stable for a longer time and dispersed better in a polymeric matrix.

The advantage of using surface-treated QDs in colloidal single photon emitters, is that it disperses the QDs and reduces the likelihood for aggregation. Such aggregation is undesired because it reduces the likelihood for single photon emission and anti-bunching statistics. The treatment technique of the present embodiments allows tuning the surfactant coverage on the surface of the perovskite QDs, and result in making it easily implemented and dispersed in a variety of polymeric matrices.

### Experimental Methods

Materials: Cs₂CO₃ (99.5% Sigma-Aldrich), Lead acetate trihydrate (Pb(CH₃COO)₂.3H₂O, 99.99% Sigma-Aldrich) Benzoyl Bromide (C₆H₅COBr, 97% Sigma-Aldrich) Octadecene (ODE, 90%, Sigma-Aldrich), Oleic Acid (OA, 90%, Sigma-Aldrich), oleylamine (OLA, 70%, Sigma-Aldrich), Hexanes (>99%, Aldrich), Ammonium Thiocyanate (99.5%, Sigma-Aldrich) Urea (>90% Sigma-Aldrich).

Nanocrystal Synthesis: 16 mg Cesium carbonate, 76 mg lead acetate trihydrate, 0.3 mL of OA, 1 mL of OLAM, and 5 mL of ODE were loaded into a 25 mL 3-neck round-bottom flask and degassed under vacuum for 1 h at 120° C. The temperature was then increased to 170° C. under nitrogen flow, and 78 ul benzoyl bromide was injected. The reaction mixture was immediately cooled down in an ice water bath to room temperature, at which point it could be disconnected from the gas manifold. 5 mL of hexane was added to the crude NC solution in aliquots to wash the reaction vessel, and the resulting mixture was centrifuged for 10 min at 8 k rpm. The supernatant was discarded, and the precipitate was redispersed in 5 mL of hexane and subsequently centrifuged for another 5 minutes 4 k rpm. The supernatant was collected. Typical concentration was determined, and ranges between 1-10 micromolar.

### UAT Synthesis:

Both urea and ammonium thiocyanate were oven dried at 100 C for 24 hours and stored in a vacuum desiccator until ready to be used. UAT was produced via gentle heating and stirring at 50 C for 3 hours with 1.4:1 molar ratio of urea to ammonium thiocyanate. Afterwards the two salts will form the deep eutectic solvent and will remain a liquid at room temperature for as long as we tested. The product is kept away from moisture as it tends to hydrate and partially recrystallize. Our QDs synthetic process was adapted from Yu et al. with slight changes¹⁸.

### UAT Treatment:

UAT is immiscible in organic solvents typical for suspension of perovskite nanocrystals such as hexane and toluene, as a result, it sinks to the bottom of the vial. A typical treatment consists of two passivation steps. In each treatment step, 1% by volume UAT was added.

After synthesis during the first washing step, 50 ul of UAT is added to the 5 ml of crude resuspension and is pulsed briefly on the vortexer. A second centrifugation step will follow, in which the treated perovskite NCs solution can be safely decanted.

In the second step 10 ul of UAT is added to 1 ml of nanocrystal solution. The sample is briefly pulsed on a vortexer to ensure mixing has occurred. The treated solution is decanted via pipette leaving the small insoluble UAT bead at the bottom to be discarded.

Samples were then characterized accordingly.

### UV-Vis Absorption, PL, and Excitation Measurements (PLE):

For optical measurements, 200 μL of the sample solution was injected to a 96-well microplate or 5 mL of the sample solution in a Take-3 holder with a quartz cuvette and measured in a Synergy H1 hybrid multimode reader. The samples were irradiated using a xenon lamp (Xe900).

Both the 5 mL and 200 μL sample solution were prepared in 1:20 dilution nanocrystals:hexane.

### PLOY and PL Lifetime Measurements:

Lifetime and photoluminescence quantum yield (PLQY) characterizations were performed using the Edinburgh FLS1000 photoluminescence spectrometer. All the samples were loaded into a quartz cuvette. The lifetime measurements were performed with multi-channel scaling (MCS) mode and conducted using a variable pulse laser (VPL). The PLQY measurements were performed with an integrating sphere holder inside the spectrometer. 2-4 mL samples were prepared in 1:20 dilution, and further diluted if necessary.

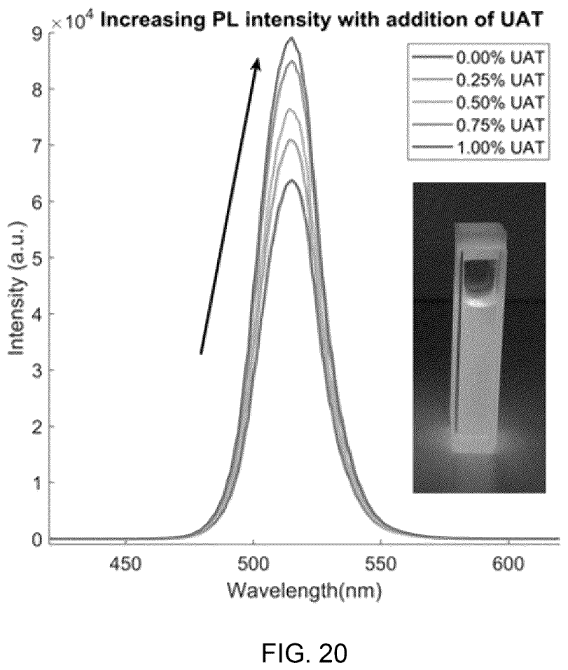

FIG. 20 shows PL emission demonstrating increased emission intensity with volumetric addition of UAT. photograph of treated NCs solution excited at UV (365 nm), (inset) Notable increase to brightness and emission by addition of UAT.

### Example 3

### Thiocyanate Surface Treatment for Quantum Emitters

This Example describes a technique for thiocyanate surface treatment. Since thiocyanate (SCN—) salts do not dissolve with NCs in their usual nonpolar solvent, the Inventors adapted a technique that uses a mix of urea and ammonium thiocyanate (UAT) for the purpose of thiocyanate surface treatment. This Example describes successful coating of NCs with thiocyanate, and provides confirmation by detailed electron microscopy. The approach described herein preserves the original crystal structure of the perovskite. It is postulated that this is akin to a surface-level upgrade rather than a fundamental change to the material's building blocks. The present Example demonstrates that application of UAT method to CsPbBr₃ nanocrystals, provides nearly perfect quantum yield and increased stability of the material against ionic changes. The experiments described below indicate that the improvement in PLQY comes from fixing defects on the NCs surface, specifically the gaps left by missing bromine atoms. Thiocyanate's ability to anchor to the NCs more firmly than the original halides leads to a more efficient and stable material, particularly useful for solar applications.

### INTRODUCTION

Metal halide perovskites have been gaining interest in recent years for their use in optoelectronic applications [Isikgor, F. H.; Zhumagali, S.; Merino, L. V. T.; Bastiani, M. De; Mcculloch, I.; Wolf, S. De. Molecular Engineering of Contact Interfaces for High-Performance Perovskite Solar Cells. www(dot)doi(dot)org/10.1038/s41578-022-00503-3, Williams, R. T.; Wolszczak, W. W.; Yan, X.; Carroll, D. L. Perovskite Quantum-Dot-in-Host for Detection of Ionizing Radiation. ACS Nano 2020, 14 (5), 5161-5169. www(dot)doi(dot)org/10.1021/acsnano.0c02529, Clinckemalie, L.; Valli, D.; Roeffaers, M. B. J.; Hofkens, J.; Pradhan, B.; Debroye, E. Challenges and Opportunities for CsPbBr₃Perovskites in Low-A Nd High-Energy Radiation Detection. ACS Energy Lett 2021, 6 (4), 1290-1314. www(dot)doi(dot)org/10.1021/acsenergylett.1c00007, Zhou, Y.; Chen, J.; Bakr, O. M.; Mohammed, O. F. Metal Halide Perovskites for X-Ray Imaging Scintillators and Detectors. ACS Energy Lett 2021, 6 (2), 739-768. www(dot)doi(dot)org/10.1021/acsenergylett.0c02430.]. As colloidal nanoparticles, their surface chemistries can be used to influence their properties and aid integration into many devices including solar cells, LED's, and sensors [Protesescu, L.; Yakunin, S.; Bodnarchuk, M. I.; Krieg, F.; Caputo, R.; Hendon, C. H.; Yang, R. X.; Walsh, A.; Kovalenko, M. v. Nanocrystals of Cesium Lead Halide Perovskites (CsPbX3, X═Cl, Br, and I): Novel Optoelectronic Materials Showing Bright Emission with Wide Color Gamut. Nano Lett 2015, 15 (6), 3692-3696. www(dot)doi(dot)org/10.1021/NL5048779/SUPPL_FILE/NL5048779 _SI_001.PDF.]. Their excellent properties have made them a popular choice for these applications. Their defect tolerance makes them robust, but even then, they are not defect-free [Huang, H.; Bodnarchuk, M. I.; Kershaw, S. V.; Kovalenko, M. V.; Rogach, A. L. Lead Halide Perovskite Nanocrystals in the Research Spotlight: Stability and Defect Tolerance. ACS Energy Lett 2017, 2 (9), 2071-2083. www(dot)doi(dot)org/10.1021/acsenergylett.7b00547, Khalfin, S.; Veber, N.; Dror, S.; Shechter, R.; Shaek, S.; Levy, S.; Kauffmann, Y.; Klinger, L.; Rabkin, E.; Bekenstein, Y. Self-Healing of Crystal Voids in Double Perovskite Nanocrystals Is Related to Surface Passivation. Adv Funct Mater 2022, 32 (15), 1-8. www(dot)doi(dot)org/10.1002/adfm.202110421].

With the onset of the solar energy revolution, there has been increasing interest in cell performance. Many issues that plague perovskite solar cells also present themselves on their nanocrystalline counterparts. The most prevalent of these defects would arise on the surface as Shockley-Read-Hall shallow trapped states, typically in the form of lead or bromide deficiencies [Pazos-Outo, L. M.; Patrick Xiao, T.; Yablonovitch, E. Fundamental Efficiency Limit of Lead Iodide Perovskite Solar Cells. 2018. www(dot)doi(dot)org/10.1021/acs.jpclett.7b03054]. These traps decrease the photoluminescence quantum yield of the nanocrystals, and subsequently the power conversion efficiency of their solar cell counterparts. Surface treatment of quantum dots can be referenced to the mid 1990's with indium phosphide (InP). Similarly, in those cases [Midid, O. I.; Sprague, J.; Lu, Z.; Nozik, A. J. Highly Efficient Band-Edge Emission from InP Quantum Dots. Appl Phys Lett 1996, 68 (22), 3150-3152. www(dot)doi(dot)org/10.1063/1.115807, Talapin, D. V.; Gaponik, N.; Borchert, H.; Rogach, A. L.; Haase, M.; Weller, H. Etching of Colloidal InP Nanocrystals with Fluorides: Photochemical Nature of the Process Resulting in High Photoluminescence Efficiency. Journal of Physical Chemistry B 2002, 106 (49), 12659-12663. www(dot)doi(dot)org/10.1021/jp026380n.], dangling bond trapped states would be responsible for the detriment to their optical properties.

To increase their photoluminescence efficiency, they were treated with fluorides which etched their surfaces, and passivated the dangling bond traps. Halides are a historically significant surface treatment for semiconductor nanocrystals of various chemical compositions.

Different passivation strategies have been employed in order to treat these defect states, typically in the form of ligands with different electronic properties and metal salts [Krieg, F.; Ochsenbein, S. T.; Yakunin, S.; ten Brinck, S.; Aellen, P.; Sü, A.; Clerc, B.; Guggisberg, D.; Nazarenko, O.; Shynkarenko, Y.; Kumar, S.; Shih, C.-J.; Infante, I.; Kovalenko, M. v. Colloidal CsPbX3 (X═Cl, Br, I) Nanocrystals 2.0: Zwitterionic Capping Ligands for Improved Durability and Stability. 2018, 3, 18. www(dot)doi(dot)org/10.1021/acsenergylett.8b00035.

(12) Woo, J. Y.; Kim, Y.; Bae, J.; Tae, #; Kim, G.; Jeong, #; Kim, W.; Lee, D. C.; Jeong, S. Highly Stable Cesium Lead Halide Perovskite Nanocrystals through in Situ Lead Halide Inorganic Passivation. Chem. Mater 2017, 29, 2. www(dot)doi(dot)org/10.1021/acs.chemmater.7b02669, ten Brinck, S.; Infante, I. Surface Termination, Morphology, and Bright Photoluminescence of Cesium Lead Halide Perovskite Nanocrystals. 2016. www(dot)doi(dot)org/10.1021/acsenergylett.6b00595].

Pseudohalides have been explored for the surface treatment of semiconductor nanocrystals of different chemistries [(14) Zhang, H.; Jang, J.; Liu, W.; Talapin, D. v. Colloidal Nanocrystals with Inorganic Halide, Pseudohalide, and Halometallate Ligands. ACS Nano 2014, 8 (7), 7359-7369. www(dot)doi(dot)org/10.1021/NN502470V/SUPPL_FILE/NN502470V_SI_001.PDF]. Thiocyanate has been demonstrated in the past as a successful agent for use in passivation of II-VI nanocrystals and recently in perovskite solar cells and nanocrystals [(15) Fafarman, A. T.; Koh, W. K.; Diroll, B. T.; Kim, D. K.; Ko, D. K.; Oh, S. J.; Ye, X.; Doan-Nguyen, V.; Crump, M. R.; Reifsnyder, D. C.; Murray, C. B.; Kagan, C. R. Thiocyanate-Capped Nanocrystal Colloids: Vibrational Reporter of Surface Chemistry and Solution-Based Route to Enhanced Coupling in Nanocrystal Solids. J Am Chem Soc 2011, 133 (39), 15753-15761. www(dot)doi(dot)org/10.1021/ja206303g. Koscher, B. A.; Swabeck, J. K.; Bronstein, N. D.; Alivisatos, A. P. Essentially Trap-Free CsPbBr3 Colloidal Nanocrystals by Post-Synthetic Thiocyanate Surface Treatment. Ye, J.; Byranvand, M. M.; Martinez, C. O.; Hoye, R. L. Z.; Saliba, M.; Polavarapu, L. Defect Passivation in Lead-Halide Perovskite Nanocrystals and Thin Films: Toward Efficient LEDs and Solar Cells. Angewandte Chemie—International Edition. John Wiley and Sons Inc Sep. 27, 2021, pp 21636-21660. www(dot)doi(dot)org/10.1002/anie.202102360.]. It improves quantum yield drastically, while maintaining structure and morphology.

Perovskites are efficient light harvesters, though their long-term stability still poses an issue. Hysteresis manifests in solar cells at the macroscale, though in the nanoscale this effect can be attributed to charge trapping. Lead thiocyanate was used as an additive in perovskite solar cells to abate these effects [(18) Ke, W.; Xiao, C.; Wang, C.; Saparov, B.; Duan, H. S.; Zhao, D.; Xiao, Z.; Schulz, P.; Harvey, S. P.; Liao, W.; Meng, W.; Yu, Y.; Cimaroli, A. J.; Jiang, C. S.; Zhu, K.; Al-Jassim, M.; Fang, G.; Mitzi, D. B.; Yan, Y. Employing Lead Thiocyanate Additive to Reduce the Hysteresis and Boost the Fill Factor of Planar Perovskite Solar Cells. Advanced Materials 2016, 28 (26), 5214-5221. www(dot)doi(dot)org/10.1002/adma.201600594]. Additionally, in films of CsPbI₃, a urea ammonium thiocyanate ionic liquid was used to exploit the coordination activities of thiocyanate for stable and efficient solar cells [Yu, B.; Shi, J.; Tan, S.; Cui, Y.; Zhao, W.; Wu, H.; Luo, Y.; Li, D.; Meng, Q. Efficient (>20%) and Stable All-Inorganic Cesium Lead Triiodide Solar Cell Enabled by Thiocyanate Molten Salts. Angewandte Chemie—International Edition 2021, 60 (24), 13436-13443. www(dot)doi(dot)org/10.1002/anie.202102466].

This Example investigates the origin of the power conversion efficiency increase, through the analogous photoluminescence quantum yield improvement using nanocrystals as a model to study the mechanism of thiocyanate as a surface treatment. This allows the modification of electronic structure as well as open more possibilities for perovskite heterostructures. The previous hypothesis suggested by Koscher claims that excess lead atoms are removed from the nanoparticle surface. Contrary to the results of Koscher, the Inventors did not find evidence suggesting Pb removal, or formation of Pb(SCN)₂.

This Example demonstrates that by utilizing an ionic liquid of thiocyanate a colloidally compatible surface treatment can be developed. The technique described herein thus overcomes the drawbacks of the ionic solid salt approach. The process of the present embodiments enhances solubility of thiocyanate by working at the liquid-liquid interface of UAT and the CsPbBr₃ nanocrystal colloid. Previous literature maintains that thiocyanate should bind to bromine vacancies on the surfaces, fulfilling those traps, subsequently increasing PLQY and ambient stability [Chen, F.; Boopathi, K. M.; Imran, M.; Lauciello, S.; Salerno, M. Thiocyanate-Treated Perovskite-Nanocrystal-Based Light-Emitting Diodes with Insight in Efficiency Roll-Off. Materials 2020, 13 (2). www(dot)doi(dot)org/10.3390/ma13020367. Lu, M.; Guo, J.; Lu, P.; Zhang, L.; Zhang, Y.; Dai, Q.; Hu, Y.; Colvin, V. L.; Yu, W. W. Ammonium Thiocyanate-Passivated Cspbi3 Perovskite Nanocrystals for Efficient Red Light-Emitting Diodes. Journal of Physical Chemistry C 2019, 123 (37), 22787-22792. www(dot)doi(dot)org/10.1021/acs.jpcc.9b06144]. The ionic liquid UAT enables a more significant concentration loading of the NCs without structural degradation. This Example describes a surface treatment for colloidal CsPbBr₃ nanocrystals exploiting the liquid-liquid interface. The results presented herein show that the binding nature of thiocyanate simultaneously improves the functionality and stability of the treated CsPbBr₃ nanocrystals.

### Experimental Methods

### Materials

Cs₂CO₃ (99.5% Sigma-Aldrich), Lead acetate trihydrate (Pb(CH₃COO)₂·3H₂O, 99.99% Sigma-Aldrich) Benzoyl Bromide (C₆H5COBr, 97% Sigma-Aldrich) Octadecene (ODE, 90%, Sigma-Aldrich), Oleic Acid (OA, 90%, Sigma-Aldrich), oleylamine (OLA, 70%, Sigma-Aldrich), Hexanes (>99%, Aldrich), n-Octane (>99%, Aldrich), Ammonium Thiocyanate (99.5%, Sigma-Aldrich) Urea (>90% Sigma-Aldrich), Lead Bromide (PbBr₂ 99.5% Sigma-Aldrich), Lead Iodide (PbI₂ 99.9% Sigma-Aldrich)

### Nanocrystal Synthesis

16 mg Cesium carbonate, 76 mg lead acetate trihydrate, 0.3 mL of OA, 1 mL of OLAM, and 5 mL of ODE were loaded into a 25 mL 3-neck round-bottom flask and degassed under vacuum for 1 hour at 120° C. The temperature was then increased to 170° C. under nitrogen flow, and 78 μl benzoyl bromide was injected. The reaction mixture was immediately cooled down in an ice water bath to room temperature, at which point it could be disconnected from the gas manifold. 5 mL of hexane was added to the crude NC solution in aliquots to wash the reaction vessel, and the resulting mixture was centrifuged for 10 minutes at 8000 rpm. The supernatant was discarded, and the precipitate was redispersed in 5 mL of hexane and subsequently centrifuged for another 5 minutes 4000 rpm. The supernatant was collected. Typical concentration was determined, and ranges between 1-10 μM. Adapted from Imran et al [J Am Chem Soc 2018, 140 (7), 2656-2664. www(dot)doi(dot)org/10.1021/jacs.7bl3477].

### UAT Synthesis

Both urea and ammonium thiocyanate were oven dried at 100° C. for 24 hours and stored in a vacuum desiccator until ready to be used. UAT was produced via gentle heating and stirring at 50° C. for 3 hours with 1.4:1 molar ratio of urea to ammonium thiocyanate. Afterwards the two salts will form the deep eutectic solvent and will remain a liquid at room temperature. It is kept away from moisture as it tends to hydrate and partially recrystallize. Adapted from Yu et al [www(dot) doi(dot)org/10.1021/acs.jpclett.7b03054, 2018].

### UAT Treatment

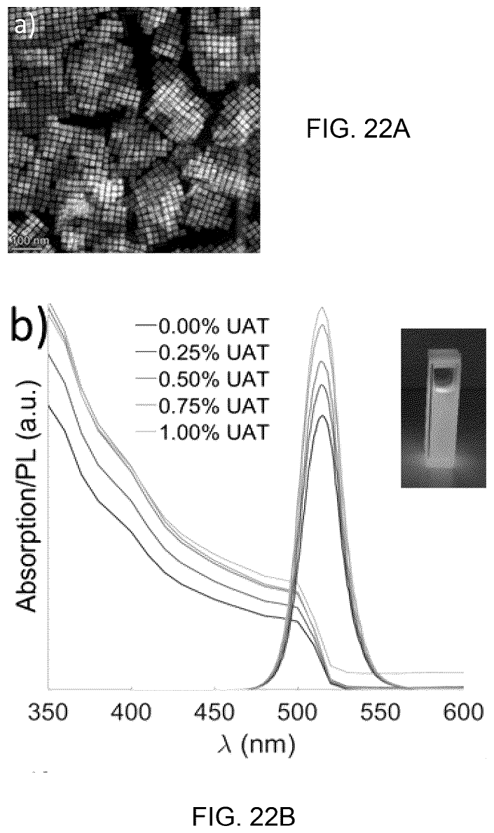

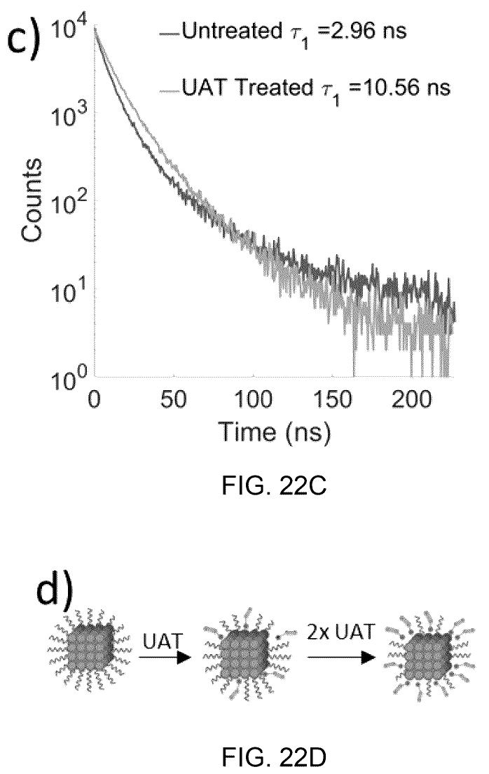

UAT is immiscible in nonpolar organic solvents typical for suspension of perovskite nanocrystals such as hexane and toluene, as a result, it sinks to the bottom of the vial. A typical treatment consists of two passivation steps (FIG. 22D). In each treatment step, 1% by volume UAT was added.

After synthesis during the first washing step, 50 μl of UAT is added to the 5 ml of crude resuspension and is pulsed briefly on the vortexer. A second centrifugation step will follow, in which the treated perovskite NCs solution can be safely decanted.

In the second step 10 μl of UAT is added to 1 ml of nanocrystal solution. The sample is briefly pulsed on a vortexer to ensure mixing has occurred. The treated solution is decanted via pipette leaving the small insoluble UAT bead at the bottom to be discarded.

The native amount of PLQY was 44%, after adding the first 1% by volume UAT the amount of PLQY, post synthesis, was 86%, after cleaning the amount of PLQY was 87%, and after adding the first 1% by volume UAT the amount the amount of PLQY, post synthesis and cleaning, was 92%.

Samples were then characterized accordingly.

UV-Vis Absorption. PL, and Excitation Measurements (PLE)

For optical measurements, 200 μL of the sample solution was injected to a 96-well microplate or 5 mL of the sample solution in a Take-3 holder with a quartz cuvette and measured in a Synergy H1 hybrid multimode reader. The samples were irradiated using a xenon lamp (Xe900). Both the 5 mL and 200 μL sample solution were prepared in 1:20 dilution nanocrystals:hexane.

### Lifetime, Photoluminescence Quantum Yield (PLOY), and Kinetic Emission Measurements

Lifetime, photoluminescence quantum yield (PLQY), and kinetic emission characterizations were performed using the Edinburgh FLS1000 photoluminescence spectrometer. All the samples were loaded into a quartz cuvette. The lifetime measurements were performed with time-correlated single-photon counting (TCSPC) mode and conducted using an efficient pulse laser (EPL) of 405 nm wavelength (EPL405). Both the lifetime and the kinetic measurements were performed with cuvette holder inside the spectrophotometer. The PLQY measurements were performed with an integrating sphere holder inside the spectrometer. Both the PLQY and the kinetic measurements were performed using xenon lamp excitation source. 2-4 mL samples were prepared in 1:20 dilution, and further diluted if necessary.

### X-Ray Diffraction (XRD) Characterizations and Two-Dimensional Grazing Incidence Wide Angle X-Ray Diffraction (2D-GIWAX)

The NC's solution was drop-cast onto a rectangular micro slide glass substrate (76 mm×26 mm) for θ-2θ measurements or sliced micro slide glass substrate (10 mm×10 mm) for 2D-GIWAX measurements. Measurements were taken using a Rigaku Smart-Lab 9 kW high-resolution X-ray diffractometer, equipped with a rotating anode X-ray source. We used a 1.54 Å (Cu Kα) wavelength. We performed a θ-2θ measurements with a 2θ range of 10°-60°, using Ge-2×200 monochromator. We performed 2D-GIWAX measurements using Hy-Pix3000 2D detector, and a 2D-SAXS/WAXS (reflection) attachment with a reflection beam stopper and aperture slit.

### Transmission Electron Microscopy (TEM) Characterization

One drop of a dilute nanocrystal solution in hexane (1:50 dilution) was cast onto a TEM grid (carbon film side, 300-mesh copper grid). The samples were observed in TEM mode with a Thermo Fisher/FEI Tecnai G2 T20 S-Twin LaB₆ TEM operated at 200 keV with a 1K×1K Gatan 694 slow scan CCD.

For characterization at the atomic scale a Thermo-Fisher/FEI Titan Themis double Cs-Corrected HR-S/TEM operated at 200 KeV was used.

The microscope is equipped with a Dual-X detector (Bruker Corporation, USA) for energy-dispersive X-ray spectroscopy (EDS) elemental mapping and a Gatan Quantum ER965 dual-EELS detector (Gatan, USA) for electron energy loss spectroscopy (EELS) analysis.

EDS maps were acquired, post processed and analyzed using the Velox software (Thermo-Fisher, USA).

### FTIR and Ultrafast 2D-IR Characterization

Infrared spectroscopy was performed with sample solutions placed between two 2-mm-thick CaF₂ windows separated with a 60 μm Teflon spacer. FTIR spectra of SCN⁻/OA/OLAM and Pb(SCN)₂/OA/OLAM solutions in octane were measured on Nicolet iS10 (Thermo Scientific), whereas SCN⁻/NCs solution was measured on Tensor 27 (Bruker) spectrometers. Each spectrum was averaged for 500 scans with 4 cm-1 resolution; all data were collected at room temperature (22° C.).

For 2D-IR spectroscopy, three mid-infrared laser pulses were generated by the 4 KHz regenerative amplifier (Solstice Ace, Spectra Physics) followed by the OPA and DFG frequency-conversion stages (Topas, Light Conversion). The central wavelength of the excitation pulses was 4.9 μm. The pulses were split into three replicas, which were focused on the sample in the BOXCAR geometry; the fourth replica pulse (local oscillator) was used for spectral interferometry to heterodyne the nonlinear signal on the 64-element liquid-nitrogen cooled array detector (Infrared Systems Development). The time interval between the first and the second pulses was scanned, and the collected data was Fourier transformed in order to obtain the excitation frequency axis. All the spectra were collected with the waiting time interval between the second and the third pulses of τ=300 fs.

### Results

This Example demonstrates a method that can be used improve perovskite surface treatment by increasing thiocyanate solubility to nonpolar solvents using ionic liquid UAT. To understand and optimize the UAT based surface treatment, the Inventors tested the solubility of UAT.

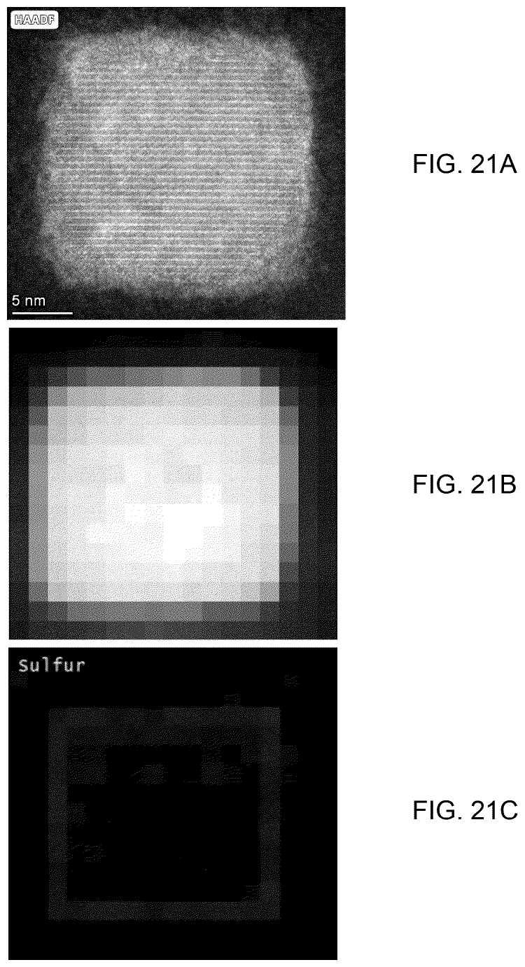

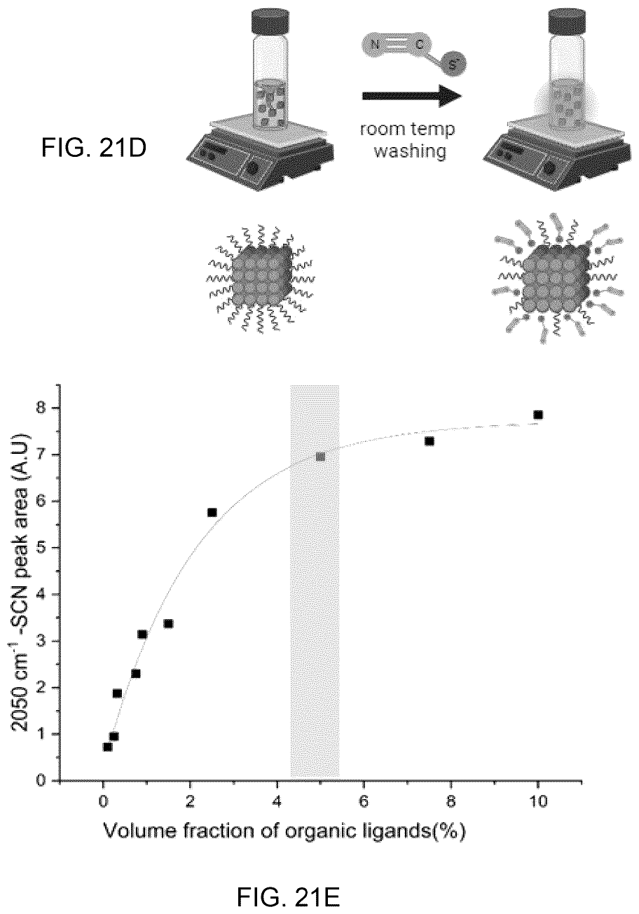

FIG. 21E shows a solubility saturation curve of thiocyanate solubility as a function of increasing the volume fraction of ligands. Here, the samples do not contain nanocrystals. The Inventors preformed FTIR measurement and observe an increase of the 2050 cm-1 peak area, representing ligand-fixated thiocyanate. As the concentration of ligands increases, the peak area of ligand-fixated thiocyanate also increases until a plateau is reached at 10% volume fraction of ligands. This shows us that the ligands dictate the solubility of thiocyanate from UAT. Additionally, with the knowledge that the ligands are in equilibrium with their solvent environment and the perovskite surface, it is surmised that the ligands-oleylamine and oleic acid are responsible, at least in part, for the thiocyanate attaching to the surface. The coordination modes of thiocyanate in an electrolytic ionic liquid are complex [Kumal, R. R.; Wimalasiri, P. N.; Servis, M. J.; Uysal, A. Thiocyanate Ions Form Antiparallel Populations at the Concentrated Electrolyte/Charged Surfactant Interface. J. Phys. Chem. Lett 2022, 13, 5081-5087. www(dot)doi(dot)org/10.1021/acs.jpclett.2c00934; Wang, Z.; Liu, T.; Long, X.; Li, Y.; Bai, F.; Yang, S. Understanding the Diverse Coordination Modes of Thiocyanate Anion on Solid Surfaces. Journal of Physical Chemistry C 2019, 123 (14), 9282-9291. www(dot)doi(dot)org/10.1021/acs.jpcc.9b01457; Gebbie, M. A.; Valtiner, M.; Banquy, X.; Fox, E. T.; Henderson, W. A.; Israelachvili, J. N. Ionic Liquids Behave as Dilute Electrolyte Solutions. Proc Natl Acad Sci USA 2013, 110 (24), 9674-9679. www(dot)doi(dot)org/10.1073/PNAS.1307871110/DCSUPPLEMENTAL/PNAS.201307871SI.P DF], though the driving force of the ligands and preferential Pb—S binding helps determining the nature of the surface treatment of the present example.

To confirm thiocyanate surface binding, the Inventors preformed electron energy loss spectroscopy (EELS) measurements. In this experiment, a lower acceleration voltage of 60 keV was used so as not to damage the sample via beam damage, and to increase the likelihood of scattering effects. This allowed to directly collect information from the lower L23-edge of the element of interest, bypassing the issue of the overlapping peaks altogether. Lead N67 and O1 do not always appear in the lower range and are not entirely present in the analysis. Additionally, EELS has the benefit of being much gentler on the sample during acquisition which allows for longer collection times. FIGS. 21A-C exhibit surface treated NC HAADF micrographs and its EELS sulfur elemental map proving sulfur attachment to the particle surface.

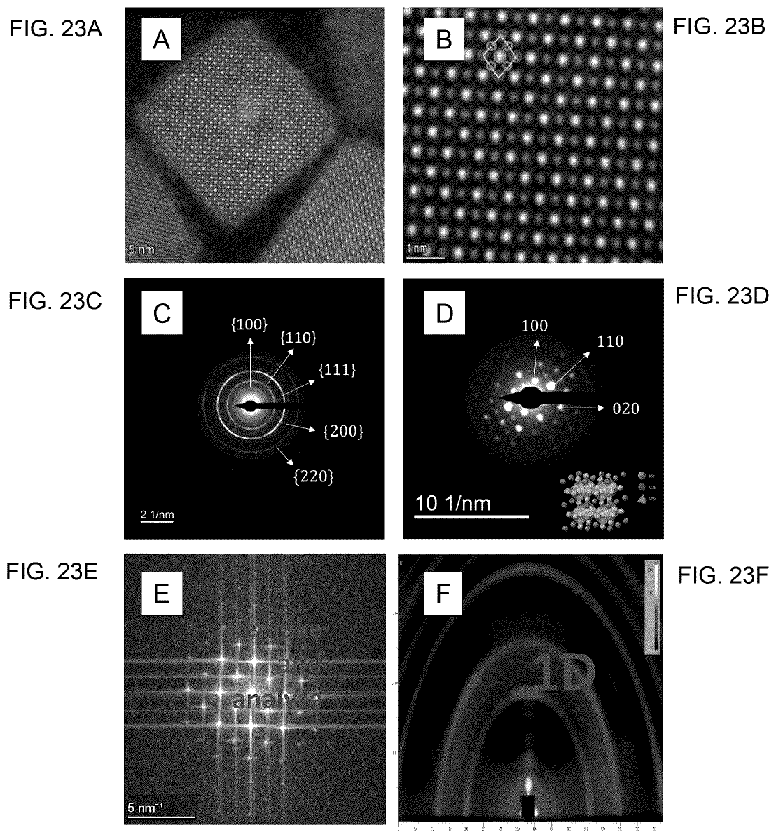

Using Beer's law for the SCN⁻ vibrational transition, the concentration of the SCN-adsorbed on the NC surface was estimated to be about 0.3 mM. Typical concentration of NCs in our experiments was 1-10 μM, suggesting that each NC is passivated with several tens to several hundred SCN⁻ anions. Since the NC's size is about 15-20 nm and has about 1500 adsorption sites on its surface (see HAADF-STEM micrographs in FIG. 23A, it is estimated that the SCN⁻ coverage is on the order of few to few tens of percent).

This Example demonstrates that thiocyanate, delivered via the ionic liquid UAT, efficiently increases the emissive characteristics of CsPbBr3 nanocrystals. Note the increase of PLQY and emission intensity with addition of up to 1% UAT (v/v) in FIG. 22B. This is attributed to passivation of shallow trapped states on the surface of the nanocrystal, a well understood phenomenon. PL emission demonstrating increased emission intensity with volumetric addition. After treatment with UAT, monoexponential decay is observed.

In terms of structural characterization, the overall morphology of the nanocrystals remains the same before and after treatment as shown in FIGS. 23A-F. The X-ray diffractogram shows that no deviation from original structure was made before and after treatment. Additionally, the peaks agree with the ICCD #01-085-6500. No change in structure from the surface treatment, by its nature, was expected; it only interact with the surface. A split peak at 15 degrees is discussed in [Toso, S.; Baranov, D.; Filippi, U.; Giannini, C.; Manna, L. Collective Diffraction Effects in Perovskite Nanocrystal Superlattices. Acc Chem Res 2023, 56 (1), 66-76. www(dot)doi(dot)org/10.1021/acs.accounts.2c00613], suggesting that this peak arises via collective diffraction effects from the formation of superlattices. Superlattices are created during the drop casting and drying process used to produce XRD samples. Evidence of these superlattices are shown in FIG. 22A which utilizes a similar drop casting method for TEM grid preparation. The HAADF STEM micrographs from FIGS. 23A-B demonstrate that the perovskite structure is fully intact, and lattice ordering is maintained. FIGS. 23C-F exhibit TEM electron diffraction of the untreated perovskite NCs.

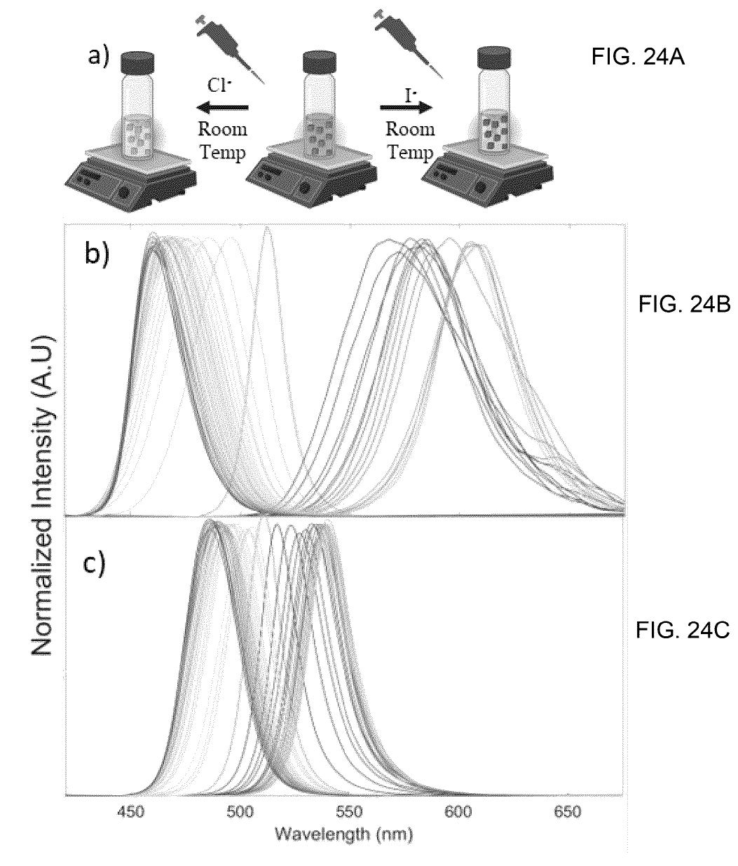

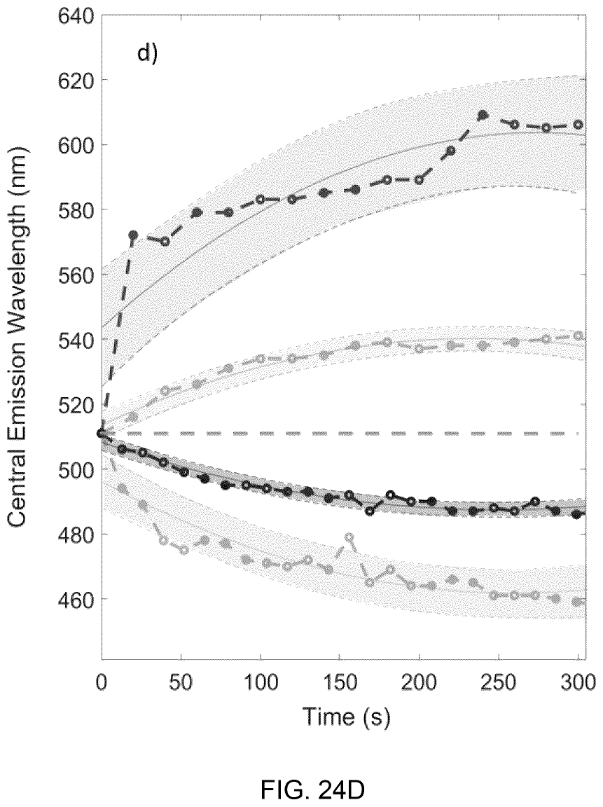

The anion exchange kinetics of thiocyanate treated surfaces was studied. FIGS. 24A-D show the in-situ ion exchange experiment. The emission spectrum that has a linear dependence to the material bandgap and halide composition was followed. In FIG. 24D, the central emission wavelength is plotted against time, demonstrating that untreated samples exchange to iodide faster and slightly slower to chloride though both on the order of a few seconds, this is consistent with the literature and is a well-established literature rates [Nedelcu, G.; Protesescu, L.; Yakunin, S.; Bodnarchuk, M. I.; Grotevent, M. J.; Kovalenko, M. v. Fast Anion-Exchange in Highly Luminescent Nanocrystals of Cesium Lead Halide Perovskites (CsPbX3, X═Cl, Br, I). Nano Lett 2015, 15 (8), 5635-5640. www(dot)doi(dot)org/10.1021/acs.nanolett.5b02404; Akkerman, Q. A.; Valerio D'innocenzo, t; Accornero, S.; Scarpellini, A.; Petrozza, A.; Prato, M.; Manna, L. Tuning the Optical Properties of Cesium Lead Halide Perovskite Nanocrystals by Anion Exchange Reactions. 2015. www(dot)doi(dot)org//10.1021/jacs.5b05602; Koscher, B. A.; Bronstein, N. D.; Olshansky, J. H.; Bekenstein, Y.; Alivisatos, A. P. Surface-vs Diffusion-Limited Mechanisms of Anion Exchange in CsPbBr 3 Nanocrystal Cubes Revealed through Kinetic Studies. J. Am. Chem. Soc 2016, 138, 12065-12068. www(dot)doi(dot)org/10.1021/jacs.6b08178.

When treated with UAT, the anion exchange is significantly slowed, by a factor of 5 for I⁻ and a factor of 3 for Cl⁻. It is hypothesized that the change in rate of exchange is directly connected to thiocyanate occupying the X sites of the perovskite, on the surface. A thiocyanate treated surface displays a much lower diffusion coefficient, preventing a facile exchange to the other anions. Thiocyanate, linear pseudohalide shares a similar electronegativity and ionic radius to both bromine and iodine (2.15-2.20 Å SCN⁻, 1.96 ÅBr⁻, 2.20 ÅI⁻) [Ren, Z.; Brinzer, T.; Dutta, S.; Garrett-Roe, S. Thiocyanate as a Local Probe of Ultrafast Structure and Dynamics in Imidazolium-Based Ionic Liquids: Water-Induced Heterogeneity and Cation-Induced Ion Pairing. 2015. www(dot)doi(dot)org/10.1021/jp512851v.]. It is assumed that its linear geometry and additional CN bond, as opposed to a single halide anion, makes it difficult to diffuse deeper into the lattice of the perovskite, and as a result is less prone to exchange. Goldschmidt tolerance and octahedral factors were also calculated, and SCN⁻ was determined to be compatible with the lattice of CsPbBr₃ Fafarman, A. T.; Koh, W. K.; Diroll, B. T.; Kim, D. K.; Ko, D. K.; Oh, S. J.; Ye, X.; Doan-Nguyen, V.; Crump, M. R.; Reifsnyder, D. C.; Murray, C. B.; Kagan, C. R. Thiocyanate-Capped Nanocrystal Colloids: Vibrational Reporter of Surface Chemistry and Solution-Based Route to Enhanced Coupling in Nanocrystal Solids. J Am Chem Soc 2011, 133 (39), 15753-15761. www(dot)doi(dot)org/10.1021/ja206303g. The XRD measurements show no structural variance between treated and untreated samples.

This Example demonstrated using both with spectroscopic and microscopic techniques that the role thiocyanate is the passivation of bromine vacancies on the surface of the nanocrystal.

The surface treatment technique of the present embodiments utilizes UAT at the liquid-liquid interface of the nanocrystal colloid. This technique was shown to increase PLQY to near unity while circumventing the issues presented with previous thiocyanate surface treatments through enhanced solubility at the liquid-liquid interface. It is thus confirmed that thiocyanate is surface bound. This agrees with EELS mapping and anion exchange kinetics. This can also be applied in cases of higher dimensions of lead halide perovskite such as 2D nanoplates, and can be demonstrated in solvent exchange experiments directed to study stability in polar solvents. This Example provides a framework compatible to other types of semiconductor nanocrystals such as IV-VI compounds or other perovskite phases and stoichiometries, and can therefore be used for the fabrication of heterostructures.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

### REFERENCES

1. Green, M. A. et al. The emergence of perovskite solar cells. Nat. Photonics 8, 506-514 (2014).
2. Jeon, N. J. et al. Compositional engineering of perovskite materials for high-performance solar cells. Nature 517, 476-480 (2015).
3. Yantara, N. et al. Inorganic Halide Perovskites for Efficient Light-Emitting Diodes. J. Phys. Chem. Lett. 6, 4360-4364 (2015).
4. Li, G., Wang, Y., Huang, L. & Sun, W. Research Progress of High-Sensitivity Perovskite Photodetectors: A Review of Photodetectors: Noise, Structure, and Materials. ACS Appl. Electron. Mater. acsaelm.1c01349 (2022) doi:10.1021/ACSAELM.1C01349.
5. Protesescu, L. et al. Nanocrystals of Cesium Lead Halide Perovskites (CsPbX3, X═Cl, Br, and I): Novel Optoelectronic Materials Showing Bright Emission with Wide Color Gamut. Nano Lett. 15, 3692-3696 (2015).
6. Bekenstein, Y., Koscher, B. A., Eaton, S. W., Yang, P. & Alivisatos, A. P. Highly Luminescent Colloidal Nanoplates of Perovskite Cesium Lead Halide and Their Oriented Assemblies. J. Am. Chem. Soc. 137, 16008-16011 (2015).
7. Brandt, R. E., Stevanovid, V., Ginley, D. S. & Buonassisi, T. Identifying defect-tolerant semiconductors with high minority-carrier lifetimes: beyond hybrid lead halide perovskites. MRS Commun. 5, 265-275 (2015).
8. Kang, J. & Wang, L. W. High Defect Tolerance in Lead Halide Perovskite CsPbBr₃. J. Phys. Chem. Lett. 8, 489-493 (2017).
9. Nedelcu, G. et al. Fast Anion-Exchange in Highly Luminescent Nanocrystals of Cesium Lead Halide Perovskites (CsPbX3, X═Cl, Br, I). Nano Lett. 15, 5635-5640 (2015).
10. Akkerman, Q. A. et al. Tuning the optical properties of cesium lead halide perovskite nanocrystals by anion exchange reactions. J. Am. Chem. Soc. 137, 10276-10281 (2015).
11. Pedersen, K. Quantum size effects in nanostructures. (2006).
12. Fox, M. Optical Properties of Solids. Volume 3 of Oxford master series in condensed matter physics (Oxford University Press, 2001).
13. Sumanth Kumar, D., Jai Kumar, B. & Mahesh, H. M. Quantum Nanostructures (QDs): An Overview. Synth. Inorg. Nanomater. 59-88 (2018) doi:10.1016/B978-0-08-101975-7.00003-8.
14. Song, J. et al. Quantum Dot Light-Emitting Diodes Based on Inorganic Perovskite Cesium Lead Halides (CsPbX3). Adv. Mater. 27, 7162-7167 (2015).
15. Liu, Y. et al. Room temperature colloidal synthesis of CsPbBr₃ nanowires with tunable length, width and composition. J. Mater. Chem. C 6, 7797-7802 (2018).
16. Dai, X., Deng, Y., Peng, X. & Jin, Y. Quantum-Dot Light-Emitting Diodes for Large-Area Displays: Towards the Dawn of Commercialization. Adv. Mater. 29, 1607022 (2017).
17. Swarnkar, A. et al. Quantum dot-induced phase stabilization of α-CsPbI3 perovskite for high-efficiency photovoltaics. Sci. 354, 92-95 (2016).
18. Wang, Y. et al. All-Inorganic Colloidal Perovskite Quantum Dots: A New Class of Lasing Materials with Favorable Characteristics. Adv. Mater. 27, 7101-7108 (2015).
19. Bi, C., Kershaw, S. V, Rogach, A. L. & Tian, J. Improved Stability and Photodetector Performance of CsPbI3 Perovskite Quantum Dots by Ligand Exchange with Aminoethanethiol. Adv. Funct. Mater. 29, 1902446 (2019).
20. Shamsi, J., Urban, A. S., Imran, M., De Trizio, L. & Manna, L. Metal Halide Perovskite Nanocrystals: Synthesis, Post-Synthesis Modifications, and Their Optical Properties. Chem. Rev. 119, 3296-3348 (2019).
21. Peng, X., Wickham, J. & Alivisatos, A. P. Kinetics of II-VI and III-V colloidal semiconductor nanocrystal growth: ‘Focusing’ of size distributions [15]. J. Am. Chem. Soc. 120,5343-5344(1998).
22. Zhang, H., Nazeeruddin, M. K. & Choy, W. C. H. Perovskite Photovoltaics: The Significant Role of Ligands in Film Formation, Passivation, and Stability. Adv. Mater. 31, 1805702 (2019).
23. Kumar, S., Jagielski, J., Marcato, T., Solari, S. F. & Shih, C. J. Understanding the Ligand Effects on Photophysical, Optical, and Electroluminescent Characteristics of Hybrid Lead Halide Perovskite Nanocrystal Solids. J. Phys. Chem. Lett. 10, 7560-7567 (2019).
24. Almeida, G. et al. Role of Acid-Base Equilibria in the Size, Shape, and Phase Control of Cesium Lead Bromide Nanocrystals. ACS Nano 12, 1704-1711 (2018).
25. Wei, Y., Cheng, Z. & Lin, J. An overview on enhancing the stability of lead halide perovskite quantum dots and their applications in phosphor-converted LEDs. Chem. Soc. Rev. 48, 310-350 (2019).
26. Yang, J., Siempelkamp, B. D., Liu, D. & Kelly, T. L. Investigation of CH3NH3PbI3 degradation rates and mechanisms in controlled humidity environments using in situ techniques. ACS Nano 9, 1955-1963 (2015).
27. Yuan, G. et al. The Degradation and Blinking of Single CsPbI3 Perovskite Quantum Dots. J. Phys. Chem. C 122, 13407-13415 (2018).
28. Misra, R. K. et al. Temperature- and Component-Dependent Degradation of Perovskite Photovoltaic Materials under Concentrated Sunlight. J. Phys. Chem. Lett. 6, 326-330 (2015).
29. Yuan, X. et al. Thermal degradation of luminescence in inorganic perovskite CsPbBr₃ nanocrystals. Phys. Chem. Chem. Phys. 19, 8934-8940 (2017).
30. Aristidou, N. et al. The Role of Oxygen in the Degradation of Methylammonium Lead Trihalide Perovskite Photoactive Layers. Angew. Chem. Int. Ed. Engl. 54, 8208-8212 (2015).
31. Liu, L. et al. Photodegradation of organometal hybrid perovskite nanocrystals: Clarifying the role of oxygen by single-dot photoluminescence. J. Phys. Chem. Lett. 10, 864-869 (2019).
32. Li, Y. et al. Light-Induced Degradation of CH3NH3PbI3 Hybrid Perovskite Thin Film. J. Phys. Chem. C 121, 3904-3910 (2017).
33. De Roo, J. et al. Highly Dynamic Ligand Binding and Light Absorption Coefficient of Cesium Lead Bromide Perovskite Nanocrystals. ACS Nano 10, 2071-2081 (2016).
34. Chen, J. et al. Photo-stability of CsPbBr₃ perovskite quantum dots for optoelectronic application. Sci. China Mater. 59, 719-727 (2016).
35. Huang, S. et al. Postsynthesis Potassium-Modification Method to Improve Stability of CsPbBr₃ Perovskite Nanocrystals. Adv. Opt. Mater. 6, 1701106 (2018).
36. Amgar, D., Binyamin, T., Uvarov, V. & Etgar, L. Near ultra-violet to mid-visible band gap tuning of mixed cation RbxCsl-xPbX3 (X═Cl or Br) perovskite nanoparticles. Nanoscale 10, 6060-6068 (2018).
37. Wang, A., Guo, Y., Muhammad, F. & Deng, Z. Controlled Synthesis of Lead-Free Cesium Tin Halide Perovskite Cubic Nanocages with High Stability. Chem. Mater. 29, 6493-6501 (2017).
38. Liu, H. et al. CsPbxMnl-xCl3 Perovskite Quantum Dots with High Mn Substitution Ratio. ACS Nano 11, 2239-2247 (2017).
39. Liu, F. et al. Highly Luminescent Phase-Stable CsPbI 3 Perovskite Quantum Dots Achieving Near 100% Absolute Photoluminescence Quantum Yield. ACS Nano 11, 10373-10383 (2017).
40. Wang, C., Chesman, A. S. R. & Jasieniak, J. J. Stabilizing the cubic perovskite phase of CsPbI 3 nanocrystals by using an alkyl phosphinic acid. Chem. Commun. 53, 232-235 (2016).
41. Raja, S. N. et al. Encapsulation of Perovskite Nanocrystals into Macroscale Polymer Matrices: Enhanced Stability and Polarization. ACS Appl. Mater. Interfaces 8, 35523-35533 (2016).
42. Zhou, Q. et al. In Situ Fabrication of Halide Perovskite Nanocrystal-Embedded Polymer Composite Films with Enhanced Photoluminescence for Display Backlights. Adv. Mater. 28, 9163-9168 (2016).
43. Raino, G. et al. Underestimated Effect of a Polymer Matrix on the Light Emission of Single CsPbBr₃ Nanocrystals. Nano Lett. 19, 3648-3653 (2019).
44. Li, Y. et al. One-Step Preparation of Long-Term Stable and Flexible CsPbBr₃ Perovskite Quantum Dots/Ethylene Vinyl Acetate Copolymer Composite Films for White Light-Emitting Diodes. ACS Appl. Mater. Interfaces 10, 15888-15894 (2018).
45. Zhang, H. et al. Embedding Perovskite Nanocrystals into a Polymer Matrix for Tunable Luminescence Probes in Cell Imaging. Adv. Funct. Mater. 27, 1604382 (2017).
46. Gisin, N., Ribordy, G., Tittel, W. & Zbinden, H. Quantum cryptography. Rev. Mod. Phys. 74, 145 (2002).
47. Bennett, C. H. & Divincenzo, D. P. Quantum information and computation. Nature 404, 247-255 (2000).
48. Kimble, H. J., Dagenais, M. & Mandel, L. Photon Antibunching in Resonance Fluorescence. Phys. Rev. Lett. 39, 691 (1977).
49. Moerner, W. E. & Kador, L. Optical detection and spectroscopy of single molecules in a solid. Phys. Rev. Lett. 62, 2535-2538 (1989).
50. Kurtsiefer, C., Mayer, S., Zarda, P. & Weinfurter, H. Stable Solid-State Source of Single Photons. Phys. Rev. Lett. 85, 290 (2000).
51. Hogele, A., Galland, C., Winger, M. & Imamoglu, A. Photon antibunching in the photoluminescence spectra of a single carbon nanotube. Phys. Rev. Lett. 100, 217401 (2008).
52. Michler, P. et al. Quantum correlation among photons from a single quantum dot at room temperature. Nature 406, 968-970 (2000).
53. Park, Y. S., Guo, S., Makarov, N. S. & Klimov, V. I. Room Temperature Single-Photon Emission from Individual Perovskite Quantum Dots. ACS Nano 9, 10386-10393 (2015).
54. Hu, F. et al. Superior Optical Properties of Perovskite Nanocrystals as Single Photon Emitters. ACS Nano 9, 12410-12416 (2015).
55. Castelletto, S., De Angelis, F. & Boretti, A. Prospects and challenges of quantum emitters in perovskites nanocrystals. Appl. Mater. Today 26, 101401 (2022).
56. Utzat, H. et al. Coherent single-photon emission from colloidal lead halide perovskite quantum dots. Science (80-). 363, (2019).
57. Rainoi, G. et al. Single Cesium Lead Halide Perovskite Nanocrystals at Low Temperature: Fast Single-Photon Emission, Reduced Blinking, and Exciton Fine Structure. ACS Nano 10, 2485-2490 (2016).
58. Cordones, A. A. & Leone, S. R. Mechanisms for charge trapping in single semiconductor nanocrystals probed by fluorescence blinking. Chem. Soc. Rev. 42, 3209-3221 (2013).
59. Schuster, J., Cichos, F. & Von Borczyskowski, C. Blinking of single molecules in various environments. Opt. Spectrosc. 98, 712-717 (2005).
60. Lin, H. et al. Fluorescence blinking, exciton dynamics, and energy transfer domains in single conjugated polymer chains. J. Am. Chem. Soc. 130, 7042-7051 (2008).
61. Vogelsang, J., Cordes, T. & Tinnefeld, P. Single-molecule photophysics of oxazines on DNA and its application in a FRET switch. Photochem. Photobiol. Sci. 8, 486-496 (2009).
62. Nirmal, M. et al. Fluorescence intermittency in single cadmium selenide nanocrystals. Nat. 383, 802-804 (1996).
63. Kuno, M., Fromm, D. P., Hamann, H. F., Gallagher, A. & Nesbitt, D. J. Nonexponential “blinking” kinetics of single CdSe quantum dots: A universal power law behavior. J. Chem. Phys. 112, 3117 (2000).
64. Georgi, C. et al. Photoinduced Luminescence Blinking and Bleaching in Individual Single-Walled Carbon Nanotubes. ChemPhysChem 9, 1460-1464 (2008).
65. Gibson, N. A., Koscher, B. A., Alivisatos, #A Paul & Leone, S. R. Excitation Intensity Dependence of Photoluminescence Blinking in CsPbBr3 Perovskite Nanocrystals. J. Phys. Chem. C 122, 2022 (2018).
66. Seth, S., Mondal, N., Patra, S. & Samanta, A. Fluorescence Blinking and Photoactivation of All-Inorganic Perovskite Nanocrystals CsPbBr3 and CsPbBr2I. J. Phys. Chem. Lett. 7, 266-271 (2016).
67. Trinh, C. T., Minh, D. N., Ahn, K. J., Kang, Y. & Lee, K. G. Organic-Inorganic FAPbBr 3 Perovskite Quantum Dots as a Quantum Light Source: Single-Photon Emission and Blinking Behaviors. ACS Photonics 5, 4937-4943 (2018).
68. Gerhard, M. et al. Microscopic insight into non-radiative decay in perovskite semiconductors from temperature-dependent luminescence blinking. Nat. Commun. 10, 1-12 (2019).
69. Chouhan, L. et al. Real-time blinking suppression of perovskite quantum dots by halide vacancy filling. ACS Nano 15, 2831-2838 (2021).
70. Brown, R. H. & Twiss, R. Q. LXXIV. A new type of interferometer for use in radio astronomy. Philos. Mag. 45, 663-682 (1954).
71. Fox, M. (Anthony M. Quantum optics: an introduction. (Oxford University Press, 2006).
72. Stansbury, J. W. & Idacavage, M. J. 3D printing with polymers: Challenges among expanding options and opportunities. Dent. Mater. 32, 54-64 (2016).
73. Martin, J. H. et al. 3D printing of high-strength aluminium alloys. Nature 549, 365-369 (2017).
74. Chen, Z. et al. 3D printing of ceramics: A review. J. Eur. Ceram. Soc. 39, 661-687 (2019).
75. Chia, H. N. & Wu, B. M. Recent advances in 3D printing of biomaterials. J. Biol. Eng. 9, 1-14 (2015).
76. Chen, M. et al. 3D Nanoprinting of Perovskites. Adv. Mater. 31, 1904073 (2019).
77. Huang, X. et al. Reversible 3D laser printing of perovskite quantum dots inside a transparent medium. Nat. Photonics 14, 82-88 (2019).
78. Xu, R. et al. Stable quantum dots/polymer matrix and their versatile 3D printing frameworks. J. Mater. Chem. C 9, 7194-7199 (2021).
79. Zhou, N. et al. Perovskite nanowire-block copolymer composites with digitally programmable polarization anisotropy. Sci. Adv. 5, (2019).
80. Okamoto, K. Wave theory of optical waveguides. Fundamentals of Optical Waveguides (Academic Press, 2006). doi:10.1016/B978-012525096-2/50002-7.
81. Zhang, J. X. J. & Hoshino, K. Molecular sensors and nanodevices. Molecular Sensors and Nanodevices (Academic Press, 2019). doi:10.1016/B978-0-12-814862-4.00005-3.
82. Smith, A. M. Polarization and magnetooptic properties of single-mode optical fiber. Appl. Opt. 17, 52-56 (1978).
83. Zhang, Y. & Guang, Z. Coupling ultrafast laser pulses into few-mode optical fibers: a numerical study of the spatiotemporal field coupling efficiency. Appl. Opt. 57, 9835-9844 (2018).
84. Liu, Z., Zhang, Z. F., Tam, H. Y. & Tao, X. Multifunctional Smart Optical Fibers: Materials, Fabrication, and Sensing Applications. Photonics 6, 48 (2019).
85. Goell, J. E. & Standley, R. D. Integrated Optical Circuits. Proc. IEEE 58, 1504-1512 (1970).
86. Arumugam, M. Optical fiber communication—An overview. Pramana 57, 849-869 (2001).
87. Chen, T. et al. Integration of Highly Luminescent Lead Halide Perovskite Nanocrystals on Transparent Lead Halide Nanowire Waveguides through Morphological Transformation and Spontaneous Growth in Water. Small 18, 2105009 (2022).
88. Abir, T., Shechter, R., Ellenbogen, T. & Bekenstein, Y. Planar Optical Waveguides Using Poly(styrene-ethylene-butylene-styrene) Activated with Inorganic Lead Halide Perovskite Nanoplates. ACS photonics 7, 2329-2336 (2020).
89. Pierini, S. et al. Highly Photostable Perovskite Nanocubes: Toward Integrated Single Photon Sources Based on Tapered Nanofibers. ACS Photonics 7, 2265-2272 (2020). Imran, M. et al. Benzoyl Halides as Alternative Precursors for the Colloidal Synthesis of Lead-Based Halide PerovskiteNanocrystals. J. Am. Chem. Soc. 140, 2656-2664 (2018).
90. Flow Rate—Hyrel3D. wwwDOThyrel3dDOTcom/wiki/index.php/Flow_Rate.
91. Gcode—Hyrel3D. wwwDOThyrel3dDOTcom/wiki/index.php/Gcode.
92. Hammer, M. OMS. wwwDOTcomputational-photonicsDOTeu/oms.html.
93. Hammer, M., Ebers, L. & Forstner, J. Hybrid coupled mode modelling of the evanescent excitation of a dielectric tube by semi-guided waves at oblique angles. Opt. Quantum Electron. 52, 1-23 (2020).
94. Ray Optics Simulation. wwwDOTricktu288DOTgithubDOTio/ray-optics/simulator/.
95. Hammer, M. FiMS. wwwDOTsiioDOTeu/fims.html.
96. Scheidt, R. A., Atwell, C. & Kamat, P. V. Tracking Transformative Transitions: From CsPbBr3 Nanocrystals to Bulk Perovskite Films. ACS Mater. Lett. 1, 8-13 (2019).
97. Rainoi, G. et al. Single Cesium Lead Halide Perovskite Nanocrystals at Low Temperature: Fast Single-Photon Emission, Reduced Blinking, and Exciton Fine Structure. ACS Nano 10, 2485-2490 (2016).
98. Becker, M. A. et al. Bright triplet excitons in caesium lead halide perovskites. Nat. 2018 5537687 553, 189-193 (2018).
99. Utzat, H. et al. Coherent single-photon emission from colloidal lead halide perovskite quantum dots. Science (80-).363, (2019).
100. Shinde, A., Gahlaut, R. & Mahamuni, S. Low-Temperature Photoluminescence Studies of CsPbBr3 Quantum Dots. J. Phys. Chem. C 121, 14872-14878 (2017).
101. De Weerd, C. et al. Energy Transfer between Inorganic Perovskite Nanocrystals. J. Phys.

Chem. C (2016) doi:10.1021/acs.jpcc.6b04768.
102. Grilli, E., Guzzi, M., Zamboni, R. & Pavesi, L. High-precision determination of the temperature dependence of the fundamental energy gap in gallium arsenide. Phys. Rev. B 45, (1992).
103. Kim, J. C. et al. Temperature-dependent micro-photoluminescence of individual CdSe self-assembled quantum dots. Appl. Phys. Lett. 75, 214 (1999).
104. Lee, S. M. et al. Temperature-Dependent Photoluminescence of Cesium Lead Halide Perovskite Quantum Dots: Splitting of the Photoluminescence Peaks of CsPbBr3 and CsPb(Br/I)3 Quantum Dots at Low Temperature. J. Phys. Chem. C 121, 26054-26062 (2017).
105. Wei, K. et al. Temperature-dependent excitonic photoluminescence excited by two-photon absorption in perovskite CsPbBr₃ quantum dots. Opt. Lett. 41, 3821-3824 (2016).
106. Li, J. et al. Temperature-dependent photoluminescence of inorganic perovskite nanocrystal films. RSC Adv. 6, 78311-78316 (2016).
107. Ai, B. et al. Low temperature photoluminescence properties of CsPbBr₃ quantum dots embedded in glasses. Phys. Chem. Chem. Phys. 19, 17349-17355 (2017).
108. Polyanskiy, M. RefractiveIndex.INFO—Refractive index database. wwwDOTrefractiveindexDOTinfo/.
109. Makarov, N. S. et al. Spectral and Dynamical Properties of Single Excitons, Biexcitons, and Trions in Cesium-Lead-Halide Perovskite Quantum Dots. Nano Lett. 16, 2349-2362 (2016).
110. De, C., Donegi, M., Bode, M. & Meijerink, A. Size- and temperature-dependence of exciton lifetimes in CdSe quantum dots. Phys. Rev. B (2006) doi:10.1103/PhysRevB.74.085320.
111. Protesescu, L. et al. Nanocrystals of Cesium Lead Halide Perovskites (CsPbX3, X═Cl, Br, and I): Novel Optoelectronic Materials Showing Bright Emission with Wide Color Gamut. Nano Lett 15, 3692-3696 (2015).
112. Pazos-Outo, L. M., Patrick Xiao, T. & Yablonovitch, E. Fundamental Efficiency Limit of Lead Iodide Perovskite Solar Cells. (2018) doi:10.1021/acs.jpclett.7b03054.
113. Zhang, H., Jang, J., Liu, W. & Talapin, D. v. Colloidal nanocrystals with inorganic halide, pseudohalide, and halometallate ligands. ACS Nano 8, 7359-7369 (2014).
114. Fafarman, A. T. et al. Thiocyanate-capped nanocrystal colloids: Vibrational reporter of surface chemistry and solution-based route to enhanced coupling in nanocrystal solids. J Am Chem Soc 133, 15753-15761 (2011).
115. Koscher, B. A., Swabeck, J. K., Bronstein, N. D. & Alivisatos, A. P. Essentially trap-free CsPbBr3 colloidal nanocrystals by post-synthetic thiocyanate surface treatment.
116. Ye, J. et al. Defect Passivation in Lead-Halide Perovskite Nanocrystals and Thin Films: Toward Efficient LEDs and Solar Cells. Angewandte Chemie—International Edition vol. 60 21636-21660 Preprint at wwwDOTdoiDOTorg/10.1002/anie.202102360 (2021).
117. Ke, W. et al. Employing Lead Thiocyanate Additive to Reduce the Hysteresis and Boost the Fill Factor of Planar Perovskite Solar Cells. Advanced Materials 28, 5214-5221 (2016).
118. Yu, B. et al. Efficient (>20%) and Stable All-Inorganic Cesium Lead Triiodide Solar Cell Enabled by Thiocyanate Molten Salts. Angewandte Chemie—International Edition 60, 13436-13443 (2021).
119. Chen, F., Boopathi, K. M., Imran, M., Lauciello, S. & Salerno, M. Thiocyanate-treated perovskite-nanocrystal-based light-emitting diodes with insight in efficiency roll-off. Materials 13, (2020).
120. Lu, M. et al. Ammonium thiocyanate-passivated cspbi3 perovskite nanocrystals for efficient red light-emitting diodes. Journal of Physical Chemistry C 123, 22787-22792 (2019).
121. Imran, M. et al. Benzoyl Halides as Alternative Precursors for the Colloidal Synthesis of Lead-Based Halide Perovskite Nanocrystals. J Am Chem Soc 140, 2656-2664 (2018).

What is claimed is:

1. A method of fabricating a light emitting device, the method comprising:
mixing a first solution containing a polymeric component with a second solution containing quantum-confinement structures, to provide a solution mixture;
dispensing said solution mixture to form a fiber, wherein said dispensing is while allowing said fiber to be self-drawn such that at least one section of said fiber has a reduced diameter relative to another section.

2. The method according to claim 1, wherein said quantum-confinement structures comprise quantum dots.

3. The method according to claim 1, wherein said quantum-confinement structures comprise quantum wires.

4. The method according to claim 1, wherein said quantum-confinement structures comprise quantum wells.

5. The method according to claim 1, wherein said second solution comprises perovskite quantum-confinement structures.

6. The method according to claim 5, wherein said perovskite quantum-confinement structures comprise perovskite quantum-dots.

7. The method according to claim 5, wherein at least a portion of said perovskite quantum-confinement structures comprises CsPbX₃, wherein X is selected from the group consisting of Cl, Br, and I.

8. The method according to claim 5, wherein at least a portion of said perovskite quantum-confinement structures comprises MAPbX₃, wherein X is selected from the group consisting of Cl, Br, and I.

9. The method according to claim 5, wherein at least a portion of said perovskite quantum-confinement structures are CsPbBr₃.

10. The method according to claim 9, wherein each of said perovskite quantum-confinement structures is CsPbBr₃.

11. The method according to claim 5, wherein at least a portion of said perovskite quantum-confinement structures comprises double perovskite quantum-confinement structures.

12. The method according to claim 1, wherein said quantum-confinement structures comprise binary compounds quantum-confinement structures.

13. The method according to claim 12, wherein at least a portion of said binary compounds quantum-confinement structures are selected from the group consisting of lead sulfide, lead selenide, cadmium selenide, cadmium sulfide, cadmium telluride, indium arsenide, and indium phosphide.

14. The method according to claim 1, comprising applying surface treatment to said quantum-confinement structures in said second solution with an anion before said mixing with said first solution.

15. The method according to claim 14, wherein said anion comprises thiocyanate.

16. The method according to claim 15, wherein said surface treatment comprises adding urea ammonium thiocyanate to said second solution.

17. The method according to claim 1, wherein said polymeric component comprises (meth) acrylic polymer component.

18. The method according to claim 17, wherein said polymeric component comprises polymethyl methacrylate (PMMA).

19. The method according to claim 1, wherein said polymeric component comprises a perfluorinated polymer component.

20. The method according to claim 19, wherein said perfluorinated polymer component comprises polyperfluorobutenyl vinyl ether.

21. The method according to claim 19, wherein said perfluorinated polymer component comprises a fluorinated polymer component.

22. The method according to claim 1, wherein said dispensing is by three-dimensional printing.

23. The method according to claim 1, wherein said dispensing is by extrusion.

24. The method according to claim 1, wherein said dispensing is by electrospinning.

25. The method according to claim 1, wherein said dispensing is over a gap between two substrates, wherein said at least one section of said reduced diameter is over said gap, and said other section is supported by at least one of said substrates.

26. The method according to claim 1, wherein at least one of a concentration of said first solution, a concentration of said second solution, and a mixing ratio of said solution mixture is selected to ensure that said section of said reduced diameter contains a single quantum-confinement structure throughout its length.

27. A light emitting device, producible by the method according to claim 1.

28. A light emitting device, comprising a single quantum-confinement structure encapsulated in a polymeric optical fiber, wherein a length of said fiber is from about 100 μm to about 10 mm, and a diameter of said fiber is from about 0.1 μm to about 20 μm.

29. A quantum computer, comprising the light emitting device of claim 28.

30. A quantum cryptology system, comprising the light emitting device of claim 28.

31. A quantum communication system, comprising the light emitting device of claim 28.
